(19) United States
(12) Patent Application Publication
(10) Pub. No.: US 2025/0118714 A1
(43) Pub. Date: Apr. 10, 2025

(54) SEMICONDUCTOR PACKAGE

(71) Applicant: Samsung Electronics Co., Ltd., Suwon-si (KR)

(72) Inventors: Keumhee Ma, Suwon-si (KR); Wansoo Park, Suwon-si (KR)

(21) Appl. No.: 18/647,087

(22) Filed: Apr. 26, 2024

(30) Foreign Application Priority Data
Oct. 10, 2023 (KR) 10-2023-0134363

(51) Int. Cl. H01L 25/10; H01L 23/00; H01L 23/31; H01L 25/065

(52) U.S. Cl. CPC H01L 25/105; H01L 23/3135; H01L 24/05; H01L 24/06; H01L 24/08; H01L 24/16; H01L 24/32; H01L 24/73; H01L 25/0657; H01L 2224/05073; H01L 2224/05575; H01L 2224/06505; H01L 2224/08121; H01L 2224/08145; H01L 2224/16148; H01L 2224/32145; H01L 2224/73204; H01L 2225/06541; H01L 2225/06555; H01L 2225/1058; H01L 2924/3511

(57) ABSTRACT

A semiconductor package includes a first semiconductor chip, a second semiconductor chip on the first semiconductor chip and directly bonded to the first semiconductor chip, a third semiconductor chip on the second semiconductor chip and directly bonded to the second semiconductor chip, and a molding layer on an upper surface of the first semiconductor chip and on a sidewall of the second semiconductor chip and a sidewall of the third semiconductor chip, wherein the third semiconductor chip includes a third semiconductor substrate including an upper surface at a level, which is lower than an upper surface of the molding layer, and a third upper insulation layer on the upper surface of the third semiconductor substrate, the upper surface of the molding layer, and an inner sidewall of the molding layer.

### CROSS-REFERENCE TO RELATED APPLICATION

This application is based on and claims priority under 35 U.S.C. § 119 to Korean Patent Application No. 10-2023-0134363, filed Oct. 10, 2023, in the Korean Intellectual Property Office, the disclosure of which is incorporated by reference herein in its entirety.

### BACKGROUND

Embodiments of the inventive concept relate to a semiconductor package, and more particularly, to a semiconductor package including stacked semiconductor chips.

In semiconductor packages, integrated circuit chips are implemented in a type suitable for electronic products. Generally, in semiconductor packages, semiconductor chips are mounted on a printed circuit board and electrically connected to each other by using a bonding wire or a bump. As the electronics industry advances, it may be required to implement a high-capacity characteristic of semiconductor packages. Also, as electronic products are miniaturized, the demands for the miniaturization of semiconductor packages are increasing.

### SUMMARY

The inventive concept provides a semiconductor package, which may be manufactured at a high yield rate.

The inventive concept provides a semiconductor package, which may have high performance and high capacity.

A semiconductor package according to an embodiment includes a first semiconductor chip, a second semiconductor chip on the first semiconductor chip and directly bonded to the first semiconductor chip, a third semiconductor chip on the second semiconductor chip and directly bonded to the second semiconductor chip, and a molding layer on an upper surface of the first semiconductor chip and on a sidewall of the second semiconductor chip and a sidewall of the third semiconductor chip, wherein the third semiconductor chip includes a third semiconductor substrate including an upper surface provided at a level which is lower than an upper surface of the molding layer, and a third upper insulation layer covering the upper surface of the third semiconductor substrate, the upper surface of the molding layer, and an inner sidewall of the molding layer.

A semiconductor package according to an embodiment includes a semiconductor substrate including wiring patterns, a first chip stack unit on the semiconductor substrate and electrically connected to the wiring patterns through first solder bumps, a second chip stack unit on the first chip stack unit and electrically connected to the first chip stack unit through second solder bumps, a first insulation film between the semiconductor substrate and the first chip stack unit and on sidewalls of the first solder bumps, and a second insulation film on sidewalls of the second solder bumps, wherein each of the first chip stack unit and the second chip stack unit includes a first semiconductor chip, a second semiconductor chip on the first semiconductor chip and directly bonded to the first semiconductor chip, and a first molding layer on an upper surface of the first semiconductor chip and on a sidewall of the second semiconductor chip.

A semiconductor package according to an embodiment includes a semiconductor substrate, a plurality of solder ball terminals on a lower surface of the semiconductor substrate including wiring patterns, a first chip stack unit on an upper surface of the semiconductor substrate and electrically connected to the wiring patterns through first solder bumps, a second chip stack unit on the first chip stack unit, the second chip stack unit including second solder bumps on a lower surface thereof, an upper dummy chip on the second chip stack unit, a gap-fill film provided between the second chip stack unit and the upper dummy chip, a first insulation film between the semiconductor substrate and the first chip stack unit and on sidewalls of the first solder bumps, a second insulation film on sidewalls of the second solder bumps, and an outer molding layer on the upper surface of the semiconductor substrate and on a sidewall of the first chip stack unit, a sidewall of the second chip stack unit, a sidewall of the first insulation film, a sidewall of the second insulation film, a sidewall of the gap-fill film, and a sidewall of the upper dummy chip, wherein each of the first chip stack unit and the second chip stack unit includes a first semiconductor chip on the first semiconductor chip, and including a first semiconductor substrate, a first lower insulation layer, a first lower pad, a first conductive via, a first upper insulation layer, and a first upper pad, a second semiconductor chip on the second semiconductor chip, and including a second semiconductor substrate, a second lower insulation layer, a second lower pad, a second conductive via, a second upper insulation layer, and a second upper pad, a third semiconductor chip including a third semiconductor substrate, a third lower insulation layer, a third lower pad, a third conductive via, a third upper insulation layer, and a third upper pad, and an inner molding layer on an upper surface of the first semiconductor chip and on a sidewall of the second semiconductor chip and a sidewall of the third semiconductor chip, the third lower pad is directly bonded to the second upper pad, and the second lower pad is directly bonded to the first upper pad.

### BRIEF DESCRIPTION OF THE DRAWINGS

Embodiments will be more clearly understood from the following detailed description taken in conjunction with the accompanying drawings in which:

FIG. 1A is a cross-sectional view illustrating a semiconductor package according to some embodiments;

FIG. 1B is an enlarged view of a region I of FIG. 1A;

FIG. 1C is an enlarged view of a region II of FIG. 1A;

FIG. 1D is an enlarged view of a region III of FIG. 1A;

FIG. 1E is a diagram of direct bonding between a first semiconductor chip and a lowermost second semiconductor chip according to some embodiments;

FIG. 1F is a diagram of direct bonding between second semiconductor chips according to some embodiments;

FIG. 1G is a diagram of direct bonding between an uppermost second semiconductor chip and a third semiconductor chip according to some embodiments;

FIGS. 2A to 2E are diagrams of a process of manufacturing a semiconductor package, according to some embodiments;

FIG. 3A is a cross-sectional view illustrating a semiconductor package according to some embodiments;

FIG. 3B is an enlarged view of a region III of FIG. 3A;

FIG. 3C is a diagram of direct bonding between an uppermost second semiconductor chip and a third semiconductor chip according to some embodiments;

FIGS. 4A and 4B are diagrams of a process of manufacturing a semiconductor package, according to some embodiments;

FIG. 5A is a cross-sectional view illustrating a semiconductor package according to some embodiments;

FIG. 5B is an enlarged view of a region IV of the semiconductor package of FIG. 5A;

FIG. 6 is a cross-sectional view illustrating a semiconductor package according to some embodiments;

FIG. 7 is a cross-sectional view illustrating a semiconductor package according to some embodiments; and

FIG. 8 is a cross-sectional view illustrating a semiconductor package according to some embodiments.

### DETAILED DESCRIPTION OF THE EMBODIMENTS

Hereinafter, example embodiments will be explained in detail with reference to the accompanying drawings. The same reference numerals are used for the same components in the drawings, and duplicate descriptions thereof are omitted. As used herein, the term “and/or” includes any and all combinations of one or more of the associated listed items. It is noted that aspects described with respect to one embodiment may be incorporated in different embodiments although not specifically described relative thereto. That is, all embodiments and/or features of any embodiments can be combined in any way and/or combination. A chip stack unit and a semiconductor package including the same according to embodiments of the inventive concept will be described below.

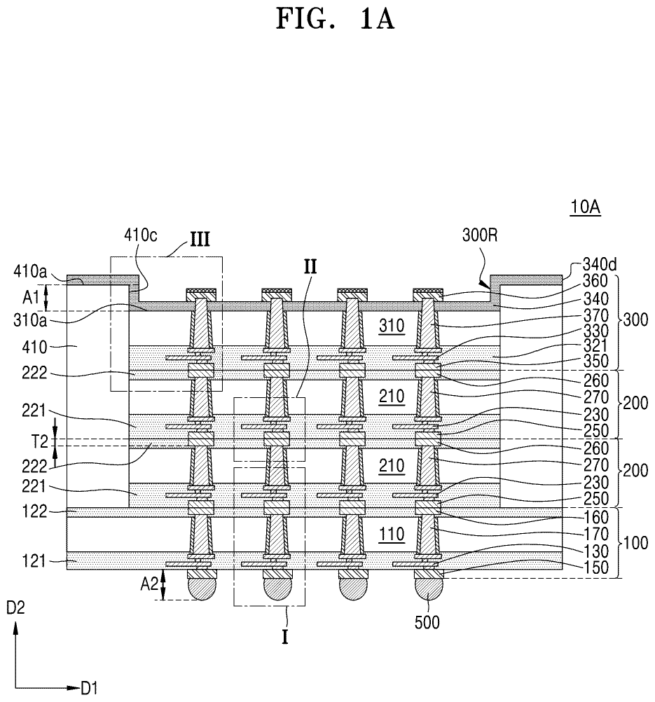

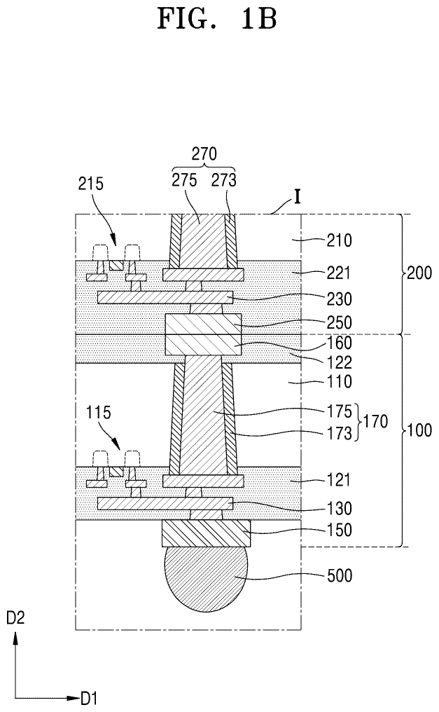

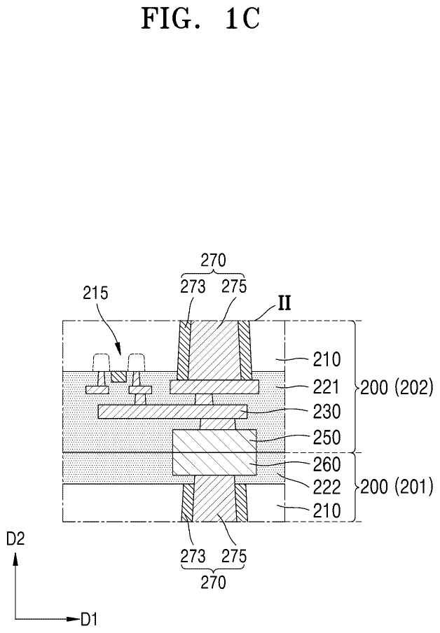

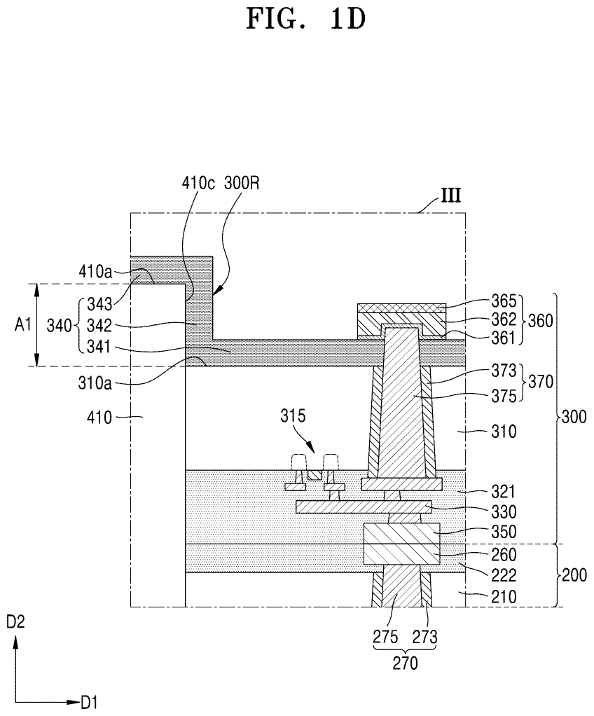

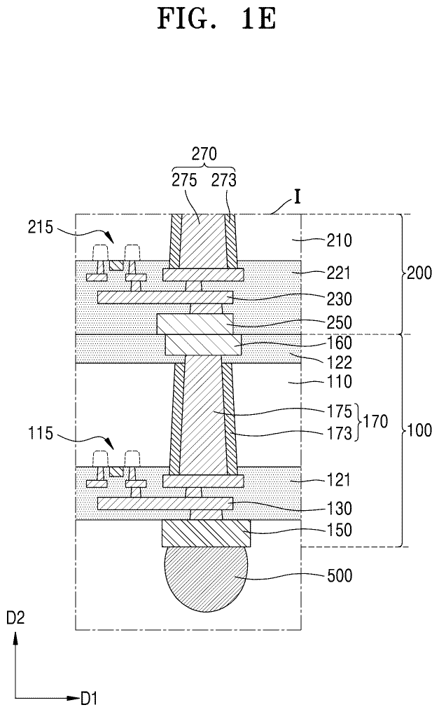

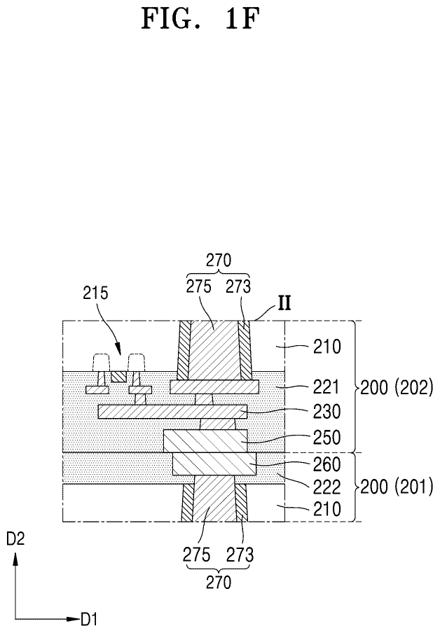

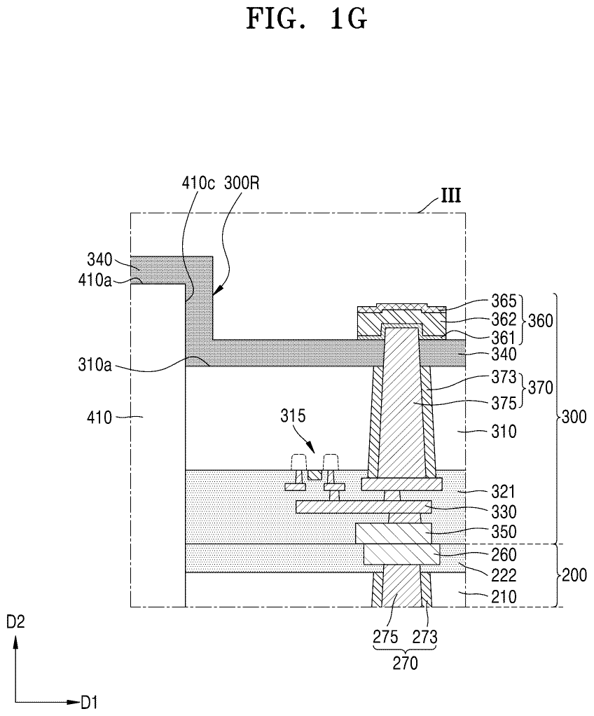

FIG. 1A is a cross-sectional view illustrating a semiconductor package according to some embodiments. FIG. 1B is an enlarged view of a region I of FIG. 1A. FIG. 1C is an enlarged view of a region II of FIG. 1A. FIG. 1D is an enlarged view of a region III of FIG. 1A.

Referring to FIGS. 1A, 1B, 1C, and 1D, the semiconductor package may be a chip stack unit 10A. The chip stack unit 10A may include a first semiconductor chip 100, a plurality of second semiconductor chips 200, a third semiconductor chip 300, solder bumps 500, and a first molding layer 410.

The first semiconductor chip 100 may be a lower (e.g., in the D2 direction) semiconductor chip. The plurality of second semiconductor chips 200 may be provided on the first semiconductor chip 100. The second semiconductor chips 200 may be vertically stacked on an upper surface of the first semiconductor chip 100. As used herein, vertical refers to the D2 direction. Thus, terms, such as lower and upper may refer to positional relationships with respect to the D2 direction. The second semiconductor chips 200 may be middle semiconductor chips. The third semiconductor chip 300 may be disposed on an uppermost second semiconductor chip 200 of the second semiconductor chips 200. For example, the second semiconductor chips 200 may be disposed between the third semiconductor chip 300 and the first semiconductor chip 100. The third semiconductor chip 300 may be the uppermost semiconductor chip. Two adjacent semiconductor chip chips of the first to third semiconductor chips 100 to 300 may be directly bonded to each other.

The first semiconductor chip 100, the second semiconductor chips 200, and the third semiconductor chip 300 may be the same semiconductor chips. The first semiconductor chip 100 may have a width that is greater than widths of the second semiconductor chips 200 and a width of the third semiconductor chip 300. The chip stack unit 10A may be manufactured by a wafer on chip (CoW) process, but embodiments are not limited thereto. A width of an arbitrary element may be measured in a direction parallel to an upper surface of the first semiconductor chip 100.

Each of the first semiconductor chip 100, the second semiconductor chips 200, and the third semiconductor chip 300 may be a memory chip, such as a dynamic random access memory (DRAM) chip. For example, the first semiconductor chip 100, the second semiconductor chips 200, and the third semiconductor chip 300 may be the same kind of semiconductor chip. For example, each of the first semiconductor chip 100, the second semiconductor chips 200, and the third semiconductor chip 300 may be a high bandwidth memory (HBM) chip. A storage capacity of the first semiconductor chip 100 may be the same as a storage capacity of each of the second semiconductor chips 200 and a storage capacity of the third semiconductor chip 300. The second semiconductor chips 200 may have the same storage capacity.

The second semiconductor chips 200 may have the same size. For example, widths of the second semiconductor chips 200 in the D1 direction may be substantially equal to one another. The second semiconductor chips 200 may have substantially the same thickness in the D2 direction. For example, sidewalls of the second semiconductor chips 200 may be vertically aligned with one another.

A width in the D1 direction of the third semiconductor chip 300 may be substantially equal to widths in the D1 direction of the second semiconductor chips 200. A sidewall of the third semiconductor chip 300 may be vertically aligned with sidewalls of the second semiconductor chips 200. Thicknesses, sizes, and widths of some elements being equal to one another may denote the equality of an error range occurring in a process. Unless separately limited herein, “perpendicular” may denote being substantially perpendicular to an upper surface of a first semiconductor substrate 110. The first direction D1 may be parallel to the upper surface of the first semiconductor substrate 110. The second direction D2 may be substantially perpendicular to the upper surface of the first semiconductor substrate 110. The second direction D2 may be a vertical direction as described above.

The number of second semiconductor chips 200 is not limited to the illustration of FIG. 1A and may be variously modified. For example, the chip stack unit 10A may include one or more second semiconductor chips 200. In other embodiments, the chip stack unit 10A may not include a second semiconductor chip 200. In this case, the third semiconductor chip 300 may be directly disposed on the first semiconductor chip 100 and may be directly bonded to the first semiconductor chip 100.

The first molding layer 410 may be disposed on the upper surface of the first semiconductor chip 100 and may be on and at least partially cover sidewalls of the second semiconductor chips 200 and a sidewall of the third semiconductor chip 300. An outer sidewall of the first molding layer 410 may be vertically aligned with a sidewall of the first semiconductor chip 100. Two adjacent semiconductor chips of the first to third semiconductor chips 100 to 300 may be directly bonded to each other, and thus, the first molding layer 410 may not extend to an upper surface of the first semiconductor chip 100 and upper surfaces of the second semiconductor chips 200. For example, the first molding layer 410 may be apart from the upper surface of the first semiconductor chip 100 and the upper surfaces of the second semiconductor chips 200. The first molding layer 410 may include an insulating polymer, such as an epoxy molding compound (EMC).

Hereinafter, elements of the first semiconductor chip 100, the second semiconductor chips 200, and the third semiconductor chip 300 are described in more detail.

Referring to FIGS. 1A and 1B, the first semiconductor chip 100 may include a first semiconductor substrate 110, first integrated circuits 115, a first lower insulation layer 121, first lower pads 150, first wiring patterns 130, first through vias 170, first upper pads 160, and a first upper insulation layer 122. The first semiconductor substrate 110 may include, for example, a semiconductor material, such as silicon (Si), germanium (Ge), or silicon germanium (SiGe). As in FIG. 1B, the first integrated circuits 115 may be provided on a lower surface of the first semiconductor substrate 110. The lower surface of the first semiconductor substrate 110 may be a frontside surface thereof. The first integrated circuits 115 may include, for example, transistors. The first integrated circuits 115 may include memory circuits.

The first lower insulation layer 121 may be provided on the lower surface of the first semiconductor substrate 110 and may be on and at least partially cover the first integrated circuits 115. The first lower insulation layer 121 may include a silicon-based insulating material. The silicon-based insulating material may include, for example, silicon oxide, silicon nitride, silicon oxynitride, and/or tetraethyl orthosilicate (TEOS). The first lower insulation layer 121 may include a plurality of stacked layers. The first wiring patterns 130 may be provided in the first lower insulation layer 121. Each of the first wiring patterns 130 may be electrically connected to at least one of the first integrated circuits 115 and the first through vias 170. Vias may be provided between the first wiring patterns 130 and may be electrically connected to the first wiring patterns 130. Herein, being electrically connected/accessed may include a direct connection/access or an indirect connection/access through another conductive element. Being electrically connected to a semiconductor chip may denote being electrically connected to integrated circuits of the semiconductor chip. An arbitrary element being connected to through vias and/or integrated circuits may denote that the arbitrary element is connected to at least one of a through via and an integrated circuit.

The first lower pads 150 may be disposed on a lower surface of the first semiconductor chip 100. For example, the first lower pads 150 may be disposed on a lower surface of the first lower insulation layer 121. The first lower pads 150 may be electrically connected to the first integrated circuits 115 and the first through vias 170 through the first wiring patterns 130. The first lower pads 150 may include metal, such as nickel (Ni) or aluminum (Al).

The first through vias 170 may be provided in the first semiconductor substrate 110 and may pass through the first semiconductor substrate 110. The first through vias 170 may further pass through at least a portion of the first lower insulation layer 121. The first through vias 170 may be spaced laterally, e.g., in the D1 direction, apart from one another. The first through vias 170 may be electrically connected to the first lower pads 150 and/or the first integrated circuits 115 through the first wiring patterns 130. As in FIG. 1B, each of the first through vias 170 may include a first conductive via 175 and a first barrier layer 173. The first conductive via 175 may include, for example, metal such as copper (Cu) or tungsten (W). The first barrier layer 173 may be disposed between the first conductive via 175 and the first semiconductor substrate 110. The first barrier layer 173 may include metal which differs from that of the first conductive via 175. The first barrier layer 173 may inhibit or prevent the metal included in the first conductive via 175 from diffusing into the first semiconductor substrate 110. The first barrier layer 173 may include a barrier metal material. The barrier metal material may include one or more of titanium (Ti), titanium nitride (TiN), tantalum (Ta), and tantalum nitride (TaN).

The first upper insulation layer 122 may be disposed on the upper surface of the first semiconductor substrate 110. The upper surface of the first semiconductor substrate 110 may be opposite to the lower surface thereof. The upper surface of the first semiconductor substrate 110 may be a backside surface thereof. The first upper insulation layer 122 may include a silicon-based insulating material. The first upper insulation layer 122 may be a multilayer. For example, the first upper insulation layer 122 may include a first layer, a second layer, and a third layer, which are stacked on the upper surface of the first semiconductor substrate 110. The second layer may include a material, which differs from that of each of the first and third layers. For example, the first layer may include silicon oxide, the second layer may include silicon nitride, and the third layer may include silicon oxide. The number and materials of layers included in the first upper insulation layer 122 may be variously modified in accordance with different embodiments. As in FIG. 1B, the first conductive via 175 may be further provided in the first upper insulation layer 122. The first barrier layer 173 may not extend into the first upper insulation layer 122. For example, the first barrier layer 173 may not be disposed between the first conductive via 175 and the first upper insulation layer 122. The first upper insulation layer 122 may be on and at least partially cover outer sidewalls of an upper portion of the first conductive via 175.

The first upper pads 160 may be disposed on the upper surface of the first semiconductor substrate 110. For example, the first upper pads 160 may be disposed in the first upper insulation layer 122. A bottom surface and sidewalls of the first upper pads 160 may be on and at least partially covered by the first upper insulation layer 122. Upper surfaces of the first upper pads 160 may not be covered by the first upper insulation layer 122. For example, the upper surfaces of the first upper pads 160 may be at substantially the same level in the D2 direction as the first upper insulation layer 122. The upper surfaces of the first upper pads 160 may be coplanar with the first upper insulation layer 122. The first upper pads 160 may include a metal, which differs from that of the first lower pads 150. The first upper pads 160 may include, for example, copper. Herein, a level of an element may denote a vertical level which is measured in a vertical direction, i.e., the D2 direction.

The first upper pads 160 may be provided on the first through vias 170 and may be electrically connected to the first through vias 170. For example, each of the first upper pads 160 may be provided on a corresponding first conductive via 175 and may contact the first conductive via 175. For example, each of the first upper pads 160 may be spaced apart from a corresponding first barrier layer 173. Lower surfaces of the first upper pads 160 may be provided at a level that is higher than an uppermost surface of the first barrier layer 173.

Unlike the illustration, the upper surface of the first semiconductor substrate 110 may be a frontside surface thereof, and a backside surface of the first semiconductor substrate 110 may be a frontside surface thereof. The first integrated circuits 115 and the first wiring patterns 130 may be disposed on the upper surface of the first semiconductor substrate 110.

Referring to FIGS. 1A, 1B, and 1C, each of the second semiconductor chips 200 may include a second semiconductor substrate 210, second integrated circuits 215, a second lower insulation layer 221, second lower pads 250, second wiring patterns 230, second through vias 270, second upper pads 260, and a second upper insulation layer 222. Unless separately described, the materials, arrangement, and electrical connection relationship of the second semiconductor substrate 210, the second integrated circuits 215, the second lower insulation layer 221, the second wiring patterns 230, the second through vias 270, and the second upper insulation layer 222 may be substantially the same as the materials, arrangement, and electrical connection relationship of the first semiconductor substrate 110, the first integrated circuits 115, the first lower insulation layer 121, the first wiring patterns 130, the first through vias 170, and the first upper insulation layer 122, respectively.

The second integrated circuits 215 may be provided on the upper surface of the second semiconductor substrate 210. The second integrated circuits 215 may be memory circuits and may be the same kind of circuits as the first integrated circuits 115.

The second lower insulation layer 221 may be provided on the lower surface of the second semiconductor substrate 210 and may cover the second integrated circuits 215. The second lower insulation layer 221 may include a plurality of stacked layers. The second wiring patterns 230 may be provided in the second lower insulation layer 221.

The second lower pads 250 may be disposed on a lower surface of the second semiconductor chip 200. For example, the second lower pads 250 may be disposed in the second lower insulation layer 221. Upper surfaces and sidewalls of the second lower pads 250 may be on and at least partially covered by the second lower insulation layer 221. The lower surfaces of the second lower pads 250 may be coplanar with a lower surface of the second lower insulation layer 221 and may be at a level in the D2 direction that is substantially the same as the lower surface of the second lower insulation layer 221. The second lower pads 250 may be electrically connected to the second integrated circuits 215 and the second through vias 270 through the second wiring patterns 230. The second lower pads 250 may include metal that differs from that of the first lower pads 150. The second lower pads 250 may include the same metal as that of the first upper pads 160. The second lower pads 250 may include, for example, copper.

The second through vias 270 may be provided in the second semiconductor substrate 210 and may pass through the second semiconductor substrate 210. The second through vias 270 may further pass through at least a portion of the second lower insulation layer 221. As in FIG. 1C, each of the second through vias 270 may include a second conductive via 275 and a second barrier layer 273. The second conductive via 275 may include, for example, a metal, such as Cu or W. The second barrier layer 273 may be disposed between the second conductive via 275 and the second semiconductor substrate 210. The second barrier layer 273 may inhibit or prevent the metal included in the second conductive via 275 from diffusing into the second semiconductor substrate 210. The second barrier layer 273 may include a metal, which differs from that of the second conductive via 275. The second barrier layer 273 may include a barrier metal material.

The second upper insulation layer 222 may be disposed on the upper surface of the second semiconductor substrate 210. The upper surface of the second semiconductor substrate 210 may be a backside surface thereof. The second upper insulation layer 222 may include a silicon-based insulating material and may be a multilayer. For example, the second upper insulation layer 222 may include a first layer, a second layer, and a third layer, which are stacked on the upper surface of the second semiconductor substrate 210. The second layer may include a material that differs from that of each of the first and third layers. For example, the first layer and the third layer may include silicon oxide, and the second layer may include silicon nitride. The number and materials of layers included in the second upper insulation layer 222 may be variously modified. As in FIG. 1C, the second conductive via 275 may be further provided in the second upper insulation layer 222. The second barrier layer 273 may not extend into the second upper insulation layer 222. For example, the second barrier layer 273 may not be disposed between the second conductive via 275 and the second upper insulation layer 222. The second upper insulation layer 222 may be on and at least partially cover outer sidewalls of an upper portion of the second conductive via 275.

The second upper pads 260 may be disposed on an upper surface of the second semiconductor substrate 210 and in the second upper insulation layer 222. For example, bottom surfaces and sidewalls of the second upper pads 260 may be at least partially covered by the second upper insulation layer 222. Upper surfaces of the second upper pads 260 may not be covered by the second upper insulation layer 222. For example, the upper surfaces of the second upper pads 260 may be at a level in the D2 direction that is substantially the same as the second upper insulation layer 222 and may be coplanar with the second upper insulation layer 222. The second upper pads 260 may include the same metal as that of the second lower pads 250. The second upper pads 260 may include, for example, copper.

The second upper pads 260 may be provided on the second through vias 270 and may be electrically connected to the second through vias 270. For example, each of the second upper pads 260 may be provided on a corresponding second conductive via 275 and may contact the second conductive via 275. Each of the second upper pads 260 may be apart from the second barrier layer 273.

Unlike the illustration, the upper surface of the second semiconductor substrate 210 may be a frontside surface thereof, and a lower surface of the second semiconductor substrate 210 may be a backside surface thereof. In this case, the second integrated circuits 215 and the second wiring patterns 230 may be disposed on the upper surface of the second semiconductor substrate 210.

Referring to FIGS. 1A and 1D, the third semiconductor chip 300 may include a third semiconductor substrate 310, third integrated circuits 315, a third lower insulation layer 321, third lower pads 350, third wiring patterns 330, third through vias 370, third upper pads 360, and a third upper insulation layer 340. The third semiconductor substrate 310, the third lower insulation layer 321, the third wiring patterns 330, the third through vias 370, and the third upper insulation layer 340 may include the same materials as those of the second semiconductor substrate 210, the second integrated circuits 215, the second lower insulation layer 221, the second wiring patterns 230, the second through vias 270, and the second upper insulation layer 222, respectively. Unless separately described, the arrangement and electrical connection relationship of the third semiconductor substrate 310, the third lower insulation layer 321, the third wiring patterns 330, and the third through vias 370 may be substantially equal or similar to the arrangement and electrical connection relationship of the second semiconductor substrate 210, the second integrated circuits 215, the second lower insulation layer 221, the second wiring patterns 230, and the second through vias 270.

The third integrated circuits 315 may be provided on the lower surface of the third semiconductor substrate 310. The third integrated circuits 315 may include, for example, transistors. The third integrated circuits 315 may be memory circuits and may be the same kind of circuits as the first integrated circuits (115 of FIG. 1B) and the second integrated circuits (215 of FIG. 1C).

The third lower insulation layer 321 may be provided on the lower surface of the third semiconductor substrate 310. The third lower insulation layer 321 may include a plurality of stacked layers. The third wiring patterns 330 may be provided in the third lower insulation layer 321.

The third lower pads 350 may be disposed on a lower surface of the third semiconductor chip 300. For example, the third lower pads 350 may be disposed in the third lower insulation layer 321. Upper surfaces and sidewalls of the third lower pads 350 may be at least partially covered by the third lower insulation layer 321. Lower surfaces of the third lower pads 350 may be coplanar with a lower surface of the third lower insulation layer 321. The third lower pads 350 may be electrically connected to the third integrated circuits 315 and the third through vias 370 through the third wiring patterns 330. The third lower pads 350 may include metal which differs from that of the first lower pads 150. The third lower pads 350 may include the same metal material as that of each of the first upper pads 160, the second lower pads 250, and the second upper pads 260. The third lower pads 350 may include, for example, copper.

The third through vias 370 may be provided in the third semiconductor substrate 310. The third through vias 370 may further pass through at least a portion of the third lower insulation layer 321. As in FIG. 1D, each of the third through vias 370 may include a third conductive via 375 and a third barrier layer 373. The third conductive via 375 may include, for example, a metal, such as Cu or W. The third barrier layer 373 may be disposed between the third conductive via 375 and the third semiconductor substrate 310. The third barrier layer 373 may inhibit or prevent the metal included in the third conductive via 375 from diffusing into the third semiconductor substrate 310. The third barrier layer 373 may include metal which differs from that of the third conductive via 375. The third barrier layer 373 may include a barrier metal material.

An upper surface 310a of the third semiconductor substrate 310 may be provided at a level in the D2 direction, which is lower than an upper surface 410a of the first molding layer 410. A level difference A1 between the upper surface 310a of the third semiconductor substrate 310 and the upper surface 410a of the first molding layer 410 may be about 50% to about 100% of the sum of a height of each of the first solder bumps 500 and thicknesses of the first lower pads 150 of FIG. 1A. The first molding layer 410 may not be provided on the upper surface 310a of the third semiconductor substrate 310. For example, the first molding layer 410 may be spaced apart from the upper surface 310a of the third semiconductor substrate 310.

The third upper insulation layer 340 may be disposed on the upper surface of the third semiconductor substrate 310, and the third upper insulation layer 340 may extend to an inner sidewall 410c and the upper surface 410a of the first molding layer 410. An outer surface 340d of the third upper insulation layer 340 may be vertically aligned with an outer sidewall of the first molding layer 410. The third upper insulation layer 340 may include a first portion 341, a second portion 342, and a third portion 343. The first portion 341 of the third upper insulation layer 340 may cover the upper surface 310a of the third semiconductor substrate 310. The second portion 342 of the third upper insulation layer 340 may be provided on the inner sidewall 410c of the first molding layer 410 and may be connected with the first portion 341. The third portion 343 of the third upper insulation layer 340 may be provided on the upper surface 410a of the first molding layer 410 and may be connected with the second portion 342. An upper surface of the third portion 343 of the third upper insulation layer 340 may be provided at a level in the D2 direction, which is higher than an upper surface of the first portion 341. Accordingly, the chip stack unit 10A may include a recess 300R. The recess 300R may be defined by the first portion 341, the second portion 342, and the third portion 343 of the third upper insulation layer 340. A bottom surface of the recess 300R may correspond to the upper surface of the first portion 341 of the third upper insulation layer 340.

The third upper insulation layer 340 may include a silicon-based insulating material. The third upper insulation layer 340 may be a multilayer. For example, the third upper insulation layer 340 may include a first layer, a second layer, and a third layer, which are stacked. In detail, the first portion 341, the second portion 342, and the third portion 343 of the third upper insulation layer 340 may respectively include the first layer, the second layer, and the third layer, which are stacked. The first layer of the third upper insulation layer 340 may conformally cover the upper surface of the third semiconductor substrate 310, an inner sidewall 410c of the first molding layer 410, and the upper surface 410a of the first molding layer 410. The first layer may include silicon oxide. The second layer of the third upper insulation layer 340 may be provided between the first layer and the second layer. The second layer may include a silicon-based insulating material which differs from that of each of the first and third layers. For example, the second layer may include silicon nitride. The number and materials of layers included in the third upper insulation layer 340 may be variously modified in accordance with different embodiments.

As in FIG. 1D, the third conductive via 375 may be further provided in the third upper insulation layer 340. For example, an end portion of the third conductive via 375 may protrude to the upper surface of the third upper insulation layer 340. The end portion of the third conductive via 375 may include an upper surface of the third conductive via 375. The upper surface of the third conductive via 375 may be provided at a level in the D2 direction, which is higher than an upper surface of the first portion 341 of the third upper insulation layer 340. The third barrier layer 373 may not extend into the third upper insulation layer 340. For example, the third barrier layer 373 may not be disposed between the third conductive via 375 and the third upper insulation layer 340. The third upper insulation layer 340 may be on and at least partially cover sidewalls of a lower portion of the third conductive via 375.

The third upper pads 360 may be provided in the recess 300R and may be disposed on the third through vias 370 and the third upper insulation layer 340. For example, the third upper pads 360 may be disposed on an upper surface of the first portion 341 of the third upper insulation layer 340. Therefore, upper surfaces of the third upper pads 360 may be at a level which is higher than the upper surface of the first portion 341 of the third upper insulation layer 340. The upper surfaces of the third upper pads 360 may be provided at a level which is lower than an upper surface of the third portion 343 of the third upper insulation layer 340. The third upper pads 360 may not be covered by the first molding layer 410.

For example, as in FIG. 1D, each of the third upper pads 360 may be provided on a corresponding third conductive via 375 and may contact the third conductive via 375. Therefore, the third upper pads 360 may be electrically connected to the third through vias 370. For example, each of the third upper pads 360 may be provided on the upper surface of the third upper insulation layer 340, sidewalls of the end portion of the third conductive via 375, and an upper surface of the end portion of the third conductive via 375.

The third upper pads 360 may include a metal, which differs from that of each of the first upper pads 160, the second lower pads 250, the second upper pads 260, and the third lower pads 350.

Each of the third upper pads 360 may include a first conductive pad 361, a second conductive pad 362, and a protection pad 365. The first conductive pad 361 may be a seed pad. The first conductive pad 361 may conformally cover an upper surface and outer sidewalls of an upper portion of the end portion of the third conductive via 375 and the upper surface of the third upper insulation layer 340. The first conductive pad 361 may include titanium (Ti), copper (Cu), or a Ti—Cu alloy. The second conductive pad 362 may be provided on the first conductive pad 361. A thickness of the second conductive pad 362 may be greater than that of the first conductive pad 361 and that of the protection pad 365. The second conductive pad 362 may include a metal, which differs from that of each of the first conductive pad 361 and the protection pad 365. The second conductive pad 362 may include a metal which differs from that of each of the first upper pads 160, the second lower pads 250, the second upper pads 260, and the third lower pads 350. The second conductive pad 362 may include the same metal as that of the first lower pads 150. For example, the second conductive pad 362 may include nickel (Ni). The protection pads 365 may be provided on the second conductive pad 362. The protection pad 365 may inhibit or prevent damage (for example, oxidation) to the second conductive pad 362. For example, the protection pad 365 may include gold (Au) or an Au alloy. For example, a thickness of the protection pad 365 may be about 1 μm or less.

Each of the third upper pads 360 may be spaced apart from the third barrier layer 233. Lower surfaces of the third upper pads 360 may be provided at a level in the D2 direction, which is higher than an uppermost surface of the third barrier layer 373.

Hereinafter, bonding between the first semiconductor chip 100 and a lowermost second semiconductor chip 200 of the second semiconductor chips 200 will be described. Hereinafter, for conciseness, one first upper pad 160 and one second lower pad 250 will be described.

Referring to FIGS. 1A and 1B, the lowermost second semiconductor chip 200 may be disposed on the first semiconductor chip 100 and may be directly bonded to the first semiconductor chip 100. Two chips being directly bonded to each other may include embodiments in which conductive elements, provided at positions facing each other, of the two chips are directly bonded to each other and embodiments in which insulation elements, provided at positions facing each other, of the two chips are directly bonded to each other. Insulation elements being directly bonded to each other may include that a chemical bond between the insulation elements is formed. Direct bonding of two chips may include hybrid bonding. For example, the second lower pad 250 may be directly disposed on the first upper pad 160 and may be directly bonded to the first upper pad 160. When performing a direct bonding process, metal atoms of the second lower pad 250 may diffuse into the first upper pad 160, and metal atoms of the first upper pad 160 may diffuse into the second lower pad 250. Therefore, an interface between the first upper pad 160 and the second lower pad 250 may not be differentiated. Accordingly, the second lower pad 250 may be solidly bonded to the first upper pad 160. In FIGS. 1A and 1B, the interface between the first upper pad 160 and the second lower pad 250 may be a virtual interface.

A second lower insulation layer 221 of the lowermost second semiconductor chip 200 may directly contact the first upper insulation layer 122 of the first semiconductor chip 100 and may be connected with the first upper insulation layer 122 through direct bonding. For example, a chemical bond between the first upper insulation layer 122 and the second lower insulation layer 221 of the lowermost second semiconductor chip 200 may be provided. The chemical bond may be a covalent bond. An interface between the first upper insulation layer 122 and the second lower insulation layer 221 of the lowermost second semiconductor chip 200 may not be differentiated. Therefore, the lowermost second semiconductor chip 200 may be solidly bonded to the first semiconductor chip 100. In FIGS. 1A and 1B, an interface between the first upper insulation layer 122 and the second lower insulation layer 221 of the lowermost second semiconductor chip 200 may be a virtual interface.

Hereinafter, bonding between the second semiconductor chips 200 is described. Hereinafter, for conciseness, one second upper pad 260 and one second lower pad 250 are described.

Referring to FIGS. 1A and 1C, the second semiconductor chips 200 may be directly bonded to each other. For example, adjacent second semiconductor chips 200 may include a first sub semiconductor chip 201 and a second sub semiconductor chip 202, as in FIG. 1C. The second sub semiconductor chip 202 may be directly disposed on the first sub semiconductor chip 201 and may be directly bonded to the first sub semiconductor chip 201. For example, a second upper pad 260 of the first sub semiconductor chip 201 may directly contact and be directly bonded to a second lower pad 250 of the second sub semiconductor chip 202. An interface between the second upper pad 260 of the first sub semiconductor chip 201 and the second lower pad 250 of the second sub semiconductor chip 202 may not be differentiated. The interface between the second upper pad 260 of the first sub semiconductor chip 201 and the second lower pad 250 of the second sub semiconductor chip 202 may be a virtual interface.

The second lower insulation layer 221 of the second sub semiconductor chip 202 may directly contact a second upper insulation layer 222 of the first sub semiconductor chip 201 and may be directly bonded to the second upper insulation layer 222. For example, a chemical bond between the second upper insulation layer 222 and the second lower insulation layer 221 of the second sub semiconductor chip 202 may be provided. The chemical bond may be a covalent bond. An interface between the second upper insulation layer 222 of the first sub semiconductor chip 201 and the second lower insulation layer 221 of the second sub semiconductor chip 202 may not be differentiated. In FIGS. 1A and 1C, an interface between the second upper insulation layer 222 and the second lower insulation layer 221 contacting each other may be a virtual interface.

Hereinafter, bonding between the third semiconductor chip 300 and an uppermost second semiconductor chip 200 of the second semiconductor chips 200 is described. Hereinafter, for conciseness, one second upper pad 260 and one third lower pad 350 are described.

Referring to FIGS. 1A and 1D, the third semiconductor chip 300 may be directly bonded to the uppermost second semiconductor chip 200. For example, a third lower pad 350 of the third semiconductor chip 300 may directly contact and be directly bonded to a second upper pad 260 of the uppermost second semiconductor chip 200. Therefore, an interface between the second upper pad 260 and the third lower pad 350 may not be differentiated. In FIGS. 1A and 1D, an interface between the second upper pad 260 and the third lower pad 350 contacting each other may be a virtual interface.

The third lower insulation layer 321 may directly contact the second upper insulation layer 222 of the uppermost second semiconductor chip 200 and may be directly bonded to the second upper insulation layer 222. For example, a chemical bond between the third lower insulation layer 321 and the second upper insulation layer 222 of the uppermost second semiconductor chip 200 may be provided. The chemical bond may be a covalent bond. Therefore, an interface between the second upper insulation layer 222 and the third lower insulation layer 321 may not be differentiated. In FIGS. 1A and 1D, an interface between the third lower insulation layer 321 and the second upper insulation layer 222 of the uppermost second semiconductor chip 200 may be a virtual interface.

According to some embodiments, two adjacent semiconductor chips of the first semiconductor chip 100, the second semiconductor chips 200, and the third semiconductor chip 300 may be directly bonded to each other, and thus, bumps and/or solders may not be provided between the two adjacent semiconductor chips. Therefore, a height of the chip stack unit 10A may be reduced, and the chip stack unit 10A may be miniaturized. Electrical connections between the first to third semiconductor chips 100 to 300 may not be limited based on the sizes, pitches, and number of the bumps and/or the solders. Therefore, the number of input/output (I/O) terminals of the first semiconductor chip 100, the second semiconductor chips 200, and the third semiconductor chip 300 may increase, and the first to third semiconductor chips 100 to 300 may be highly integrated and have high performance.

Solder bumps 500 may be provided on a lower surface of the first semiconductor chip 100. The solder bumps 500 may be disposed on, for example, lower surfaces of the first lower pads 150 and may be electrically connected to the first lower pads 150. Accordingly, each of the solder bumps 500 may be electrically connected to at least one of the first semiconductor chip 100, the second semiconductor chips 200, and the third semiconductor chip 300. The solder bumps may include metal, such as a solder material. The solder material may include tin (Sn), silver (Ag), zinc (Zn), and/or an alloy thereof.

FIG. 1E is a diagram of bonding between a first semiconductor chip and a lowermost second semiconductor chip according to some embodiments and corresponds to an enlarged view of a region I of the semiconductor package 10A of FIG. 1A. Hereinafter, descriptions which are the same as or similar to the above descriptions are omitted.

Referring to FIG. 1E, the lowermost second semiconductor chip 200 may be directly bonded to the first semiconductor chip 100. For example, a lower surface of a second lower pad 250 of the lowermost semiconductor chip 200 may be directly bonded to an upper surface of the first upper pad 160. On the other hand, a sidewall of the second lower pad 250 may not be perpendicular aligned with a sidewall of the first upper pad 160. The sidewall of the second lower pad 250 may be offset-disposed in a first direction D1 or a direction opposite to the first direction D1, with respect to the sidewall of the first upper pad 160.

FIG. 1F is a diagram of bonding between second semiconductor chips according to some embodiments and corresponds to an enlarged view of a region II of the semiconductor package of FIG. 1A.

Referring to FIG. 1F, adjacent second semiconductor chips 200 may be directly bonded to each other. For example, a lower surface of a second lower pad 250 of the second sub semiconductor chip 202 may be directly bonded to an upper surface of a second upper pad 260 of the first sub semiconductor chip 201. In other embodiments, a sidewall of the second lower pad 250 may be offset-disposed in a first direction D1 or a direction opposite to the first direction D1, with respect to a sidewall of the second upper pad 260. The sidewall of the second lower pad 250 may not be perpendicular aligned with the sidewall of the second upper pad 260.

FIG. 1G is a diagram of bonding between an uppermost second semiconductor chip and a third semiconductor chip according to some embodiments and corresponds to an enlarged view of a region III of the semiconductor package of FIG. 1A.

Referring to FIG. 1G, the third semiconductor chip 300 may be directly bonded to the uppermost second semiconductor chip 200. For example, a lower surface of the third lower pad 350 may be directly bonded to an upper surface of the second upper pad 260 of the uppermost second semiconductor chip 200. In other embodiments, a sidewall of the third lower pad 350 may be offset-disposed in a first direction D1 or a direction opposite to the first direction D1, with respect to a sidewall of the second upper pad 260. The sidewall of the third lower pad 350 may not be perpendicular aligned with the sidewall of the second upper pad 260.

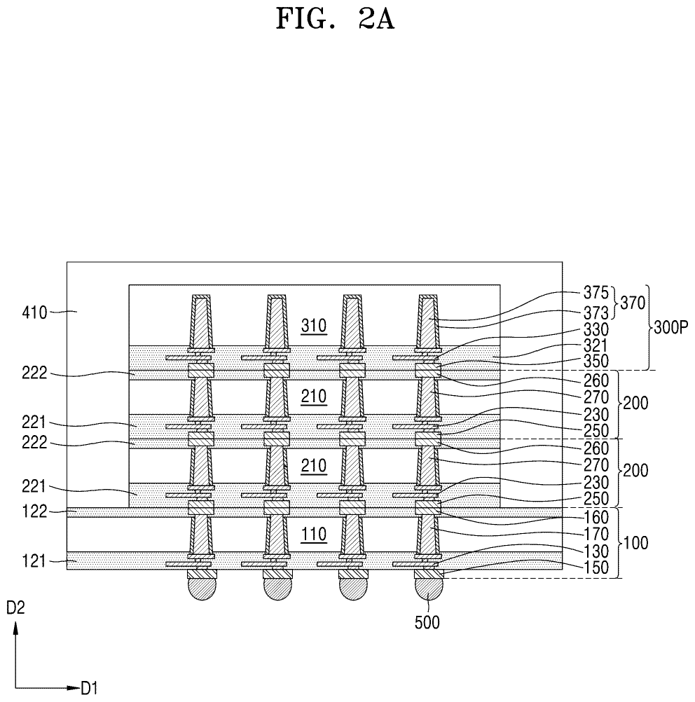

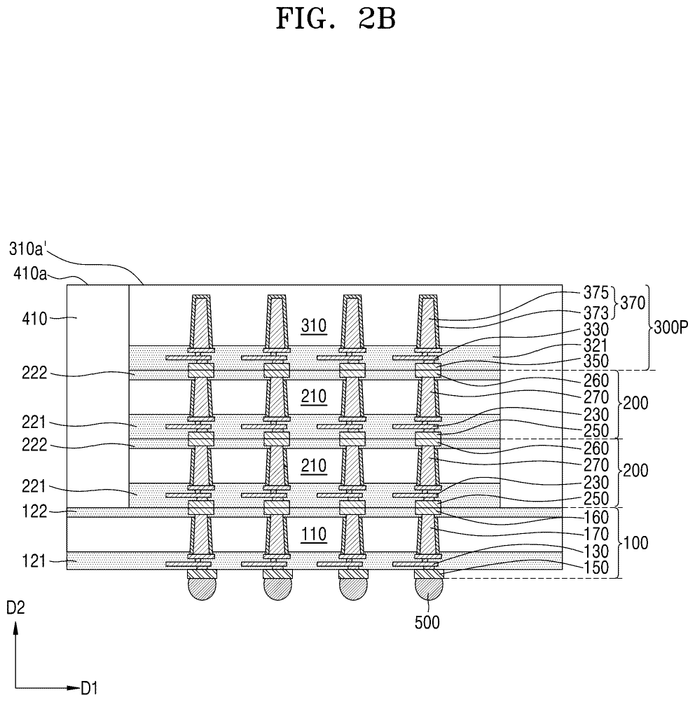

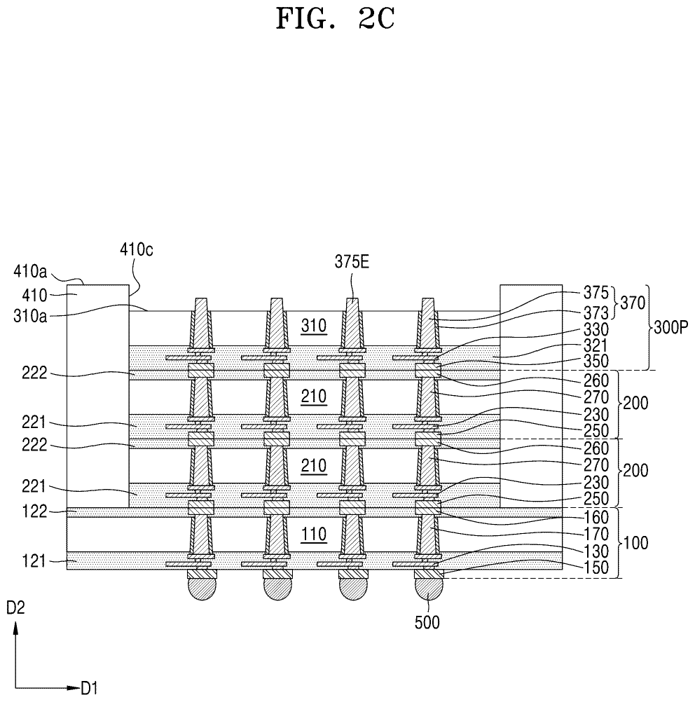

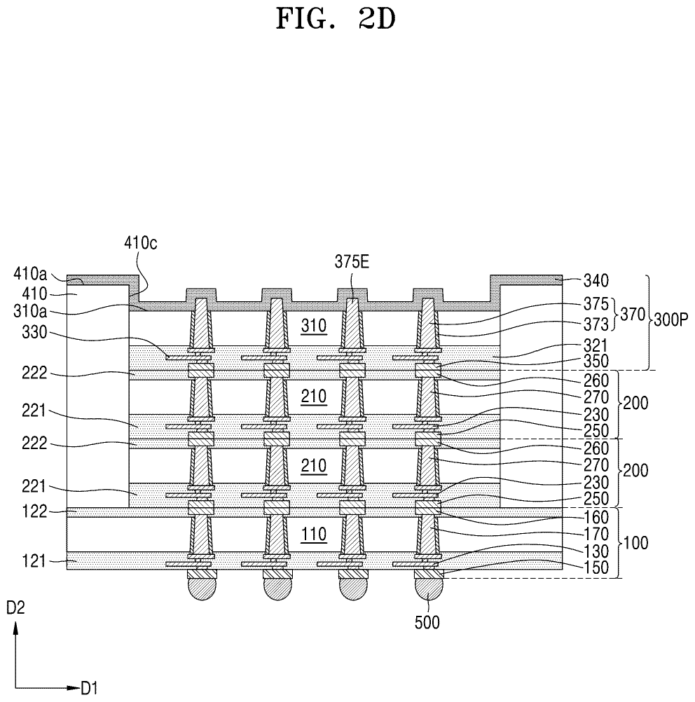

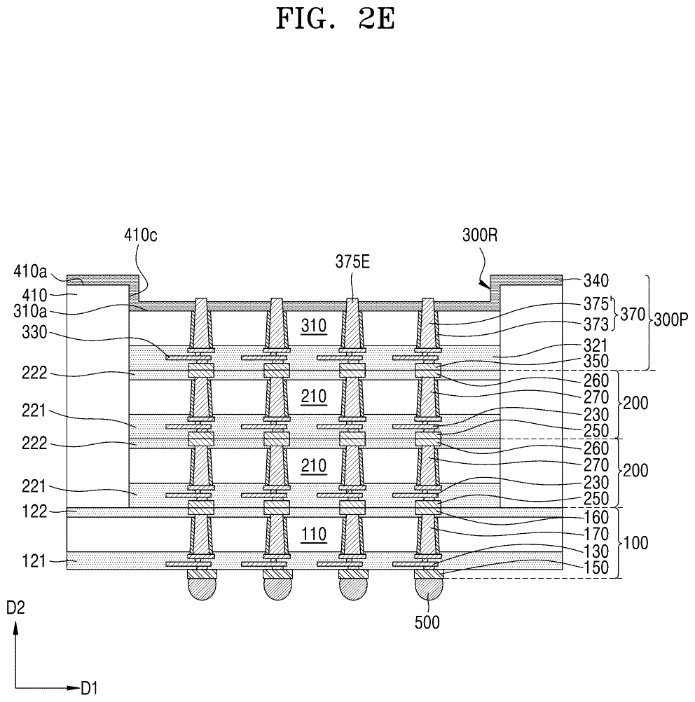

FIGS. 2A to 2E are diagrams of a process of manufacturing a semiconductor package, according to some embodiments. Hereinafter, descriptions which are the same as or similar to the above descriptions are omitted.

Referring to FIG. 2A, a first semiconductor chip 100 may be prepared. The first semiconductor chip 100 may be as described above with reference to FIGS. 1A and 1B. However, the first semiconductor chip 100 may be prepared at a wafer level. As described above with reference to FIGS. 1A, 1B, and 1C, a second semiconductor chip 200 may be prepared at a chip level. The second semiconductor chip 200 may be disposed on the first semiconductor chip 100 and may be directly bonded to the first semiconductor chip 100 by a thermal compression process. For example, an operation of directly bonding the second semiconductor chip 200 to the first semiconductor chip 100 may include an operation of applying heat and pressure to the first semiconductor chip 100 and the second semiconductor chip 200.

The arrangement of the second semiconductor chip 200 may be repeatedly performed, and thus, a plurality of stacked second semiconductor chips 200 may be manufactured. A thermal compression process may be performed on the second semiconductor chips 200, and the second semiconductor chips 200 may be directly bonded to each other.

A third preliminary semiconductor chip 300P may be prepared at a chip level. The third preliminary semiconductor chip 300P may include a first semiconductor substrate 110, first integrated circuits 115, a first lower insulation layer 121, first lower pads 150, first wiring patterns 130, and first through vias 170, which are as described above with reference to FIGS. 1A and 1D, and may not include the first upper pads 160 and the first upper insulation layer 122. In this case, an upper surface of each of the third through vias 370 may be provided in a third semiconductor substrate 310. A third barrier layer 373 may be provided between the third semiconductor substrate 310 and a third conductive via 375 and may cover an upper surface and sidewalls of the third conductive via 375.

The third preliminary semiconductor chip 300P may be disposed on an uppermost second semiconductor chip 200, and the third preliminary semiconductor chip 300P may be directly bonded to the uppermost second semiconductor chip 200. Direct bonding between the uppermost second semiconductor chip 200 and the third semiconductor chip 300 may be performed by a thermal compression process.

A first molding layer 410 may be disposed on an upper surface of the first semiconductor chip 100 and may cover sidewalls of the second semiconductor chips 200, a sidewall of the third preliminary semiconductor chip 300P, and an upper surface of the preliminary third semiconductor chip 300P. The upper surface of the preliminary third semiconductor chip 300P may correspond to an upper surface of the third semiconductor substrate 310. Formation of the first molding layer 410 may be performed at a wafer level.

Referring to FIG. 2B, a grinding process may be performed on the first molding layer 410 to expose the upper surface of the preliminary third semiconductor chip 300P. The grinding process may include a chemical mechanical polishing (CMP) process. An upper surface 310a′ of the third semiconductor substrate 310 may be exposed by the grinding process. The upper surface 310a′ of the third semiconductor substrate 310 may be provided at a level in the D2 direction which is substantially the same as an upper surface 410a of the first molding layer 410.

Referring to FIG. 2C, an etching process may be performed on the upper surface 310a′ of the third semiconductor substrate 310, and thus, an upper portion of the third semiconductor substrate 310 may be removed. Therefore, the upper surface 310a′ of the third semiconductor substrate 310 may be recessed, and at least a portion of an inner sidewall of the first molding layer 410 may be exposed. For example, a recessed upper surface 310a of the third semiconductor substrate 310 may be provided at a level in the D2 direction, which is lower than the upper surface 410a of the first molding layer 410. End portions of the third through vias 370 may be exposed by the etching process. For example, a portion of the third barrier layer 373 may be exposed. The exposed portion of the third barrier layer 373 may be further removed, and thus, an end portion 375E of the third conductive via 375 may be exposed. The end portion 375E of the third conductive via 375 may protrude from the upper surface 310a of the third semiconductor substrate 310. A remaining uppermost surface of the third barrier layer 373 may be provided at a level in the D2 direction, which is equal or similar to the upper surface 310a of the third semiconductor substrate 310.

Referring to FIG. 2D, a third upper insulation layer 340 may be formed on the third semiconductor substrate 310, the exposed end portion 375E of the third conductive via 375, the inner sidewall 410c of the first molding layer 410, and the upper surface 410a of the first molding layer 410 and may conformally at least partially cover the upper surface of the third semiconductor substrate 310, an upper surface and sidewalls of an upper portion of the end portion 375E of the third conductive via 375, the inner sidewall 410c of the first molding layer 410, and the upper surface 410a of the first molding layer 410. An operation of forming the third upper insulation layer 340 may be performed by a deposition process. The third upper insulation layer 340 may include a first layer, a second layer, and a third layer, which are stacked. Each of the first layer, the second layer, and the third layer may be performed by the deposition process.

Referring to FIG. 2E, a portion of the third upper insulation layer 340 may be removed, and thus, the upper portion of the end portion 375E of the third conductive via 375 may be exposed. For example, the upper surface of the end portion 375E of the third conductive via 375 may be provided at a level in the D2 direction, which is higher than an upper surface of the third upper insulation layer 340 on the upper surface of the third semiconductor substrate 310. A lower portion of the end portion 375E of the third conductive via 375 may be provided in the third upper insulation layer 340, and sidewalls of the lower portion of the end portion 375E of the third conductive via 375 may be at least partially covered by the third upper insulation layer 340.

Referring to FIG. 2E in conjunction with FIGS. 1A and 1D, a third upper pad 360 may be formed on an upper portion of the exposed end portion 375E of the third conductive via 375. The third upper pad 360 may be provided in plurality, and the plurality of third upper pads 360 may be respectively and electrically connected to the third through vias 370. The third upper pads 360 may be formed by a single process. Each of the third upper pads 360 may include a first conductive pad 361, a second conductive pad 362, and a protection pad 365 as illustrated in FIG. 1D. The first conductive pad 361 may be formed by a sputtering process or a deposition process. The deposition process may include a physical vapor deposition (CVD) process. An operation of forming the second conductive pad 362 may include an operation of performing an electro-plating process, which uses the first conductive pad 361 as an electrode. The protection pad 365 may be formed on the second conductive pad 362 and may protect the second conductive pad 362. Accordingly, manufacturing of the third semiconductor chip 300 including the third semiconductor substrate 310, the third integrated circuits 315, the third lower insulation layer 321, the third lower pads 350, the third wiring patterns 330, the third through vias 370, the third upper pads 360, and the third upper insulation layer 340 may be completed. Furthermore, manufacturing of the chip stack unit 10A may be completed.

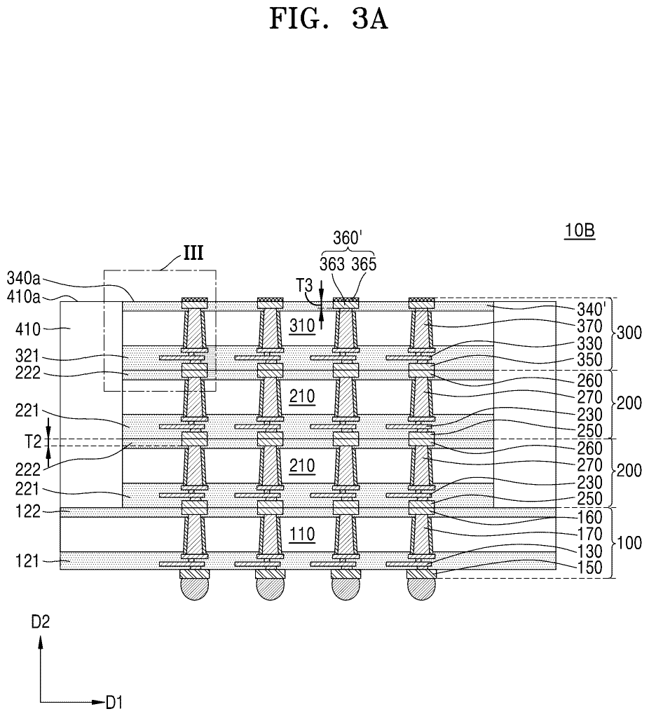

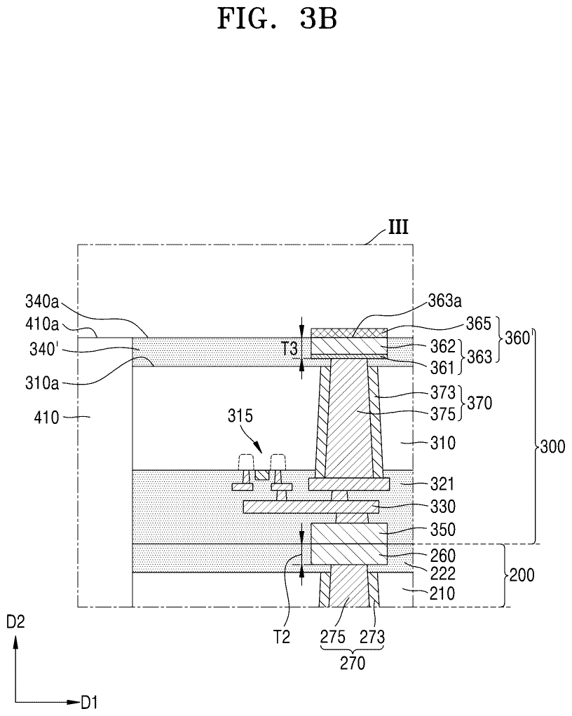

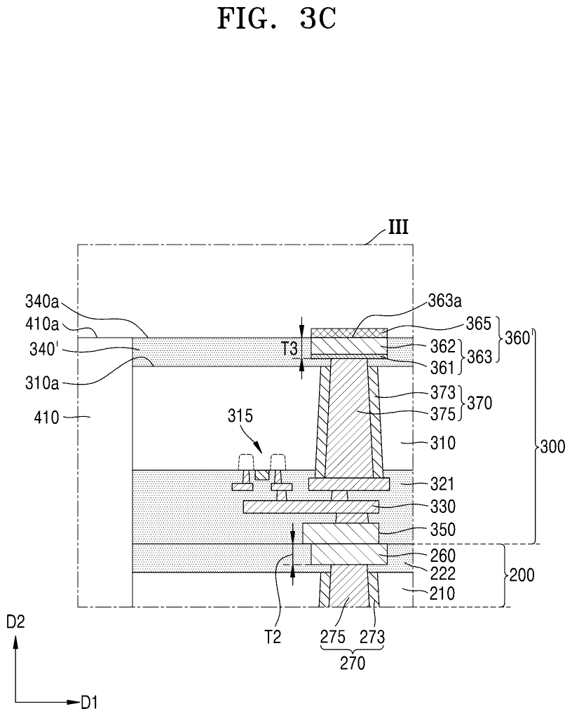

FIG. 3A is a cross-sectional view illustrating a semiconductor package according to some embodiments. FIG. 3B is an enlarged view of a region III of FIG. 3A.

Referring to FIGS. 3A and 3B, the semiconductor package may be a chip stack unit 10B. The chip stack unit 10B may include a first semiconductor chip 100, a plurality of second semiconductor chips 200, a third semiconductor chip 300, solder bumps 500, and a first molding layer 410. Two adjacent semiconductor chip chips of the first to third semiconductor chips 100 to 300 may be directly bonded to each other. The first semiconductor chip 100, the second semiconductor chips 200, the solder bumps 500, and the first molding layer 410 may be substantially the same as the descriptions of FIGS. 1A to 1C.

The third semiconductor chip 300 may include a third semiconductor substrate 310, third integrated circuits 315, a third lower insulation layer 321, third lower pads 350, third wiring patterns 330, and third through vias 370, which are as described above with reference to FIGS. 1A and 1D. The third semiconductor chip 300 may include third upper pads 360′ and a third upper insulation layer 340′. In other embodiments, the third upper insulation layer 340′ may not extend to an upper surface 410a of the first molding layer 410. An upper surface 340a of the third upper insulation layer 340′ may be provided at a level in the D2 direction, which is substantially the same as the upper surface 410a of the first molding layer 410. The third upper insulation layer 340′ may include a first layer, a second layer, and a third layer, which are stacked on an upper surface 310a of the third semiconductor chip 300.

The third upper pads 360′ may be provided in the third upper insulation layer 340′ and may contact the third through vias 370. The third upper pads 360′ may include a conductive pad 363 and a protection pad 365. As in FIG. 3B, the conductive pad 363 may include a first conductive pad 361 and a second conductive pad 362. The second conductive pad 362 may be provided on an upper surface of the first conductive pad 361. A thickness of the second conductive pad 362 may be greater than that of the first conductive pad 361. The second conductive pad 362 may include the same metal as that of each of the first upper pads 160, the second lower pads 250, the second upper pads 260, and the third lower pads 350. The second conductive pad 362 may include, for example, copper.

The conductive pad 363 may be provided in the third upper insulation layer 340′. A lower surface and a sidewall of the conductive pad 363 may be at least partially covered by the third upper insulation layer 340′. An upper surface 363a of the conductive pad 363 may be coplanar with the third upper insulation layer 340′. The upper surface 363a of the conductive pad 363 may be an upper surface of the second conductive pad 362. A thickness T3 of the conductive pad 363 may be less than or equal to a thickness T2 of the second upper pads 260. For example, the thickness T3 of the conductive pad 363 may be about 20% to about 100% of the thickness T2 of the second upper pads 260. The thickness T3 of the conductive pad 363 may include a thickness of the first conductive pad 361 and a thickness of the second conductive pad 362.

The protection pad 365 may at least partially cover an upper surface 363a of the conductive pad 363. An upper surface of the protection pad 365 may be provided at a level in the D2 direction, which is higher than the upper surface 340a of the third upper insulation layer 340′. A thickness of the protection pad 365 may be less than that of the second conductive pad 362. The protection pad 365 may include gold (Au) or an Au alloy. Hereinafter, for conciseness of the drawings, in the drawings except FIGS. 3B and 3C, it is not illustrated that the first conductive pad 361 and the second conductive pad 362 are separately differentiated from each other. However, embodiments of the inventive concept are not limited thereto.

FIG. 3C is a diagram of bonding between an uppermost second semiconductor chip and a third semiconductor chip according to some embodiments and corresponds to an enlarged view of a region III of the semiconductor package of FIG. 3A.

Referring to FIG. 3C, the third semiconductor chip 300 may be directly bonded to an uppermost second semiconductor chip 200. For example, a lower surface of the third lower pad 350 may be directly bonded to an upper surface of a second upper pad 260 of the uppermost second semiconductor chip 200. In other embodiments, a sidewall of the third lower pad 350 may be offset-disposed in a first direction D1 or a direction opposite to the first direction D1, with respect to a sidewall of the second upper pad 260.

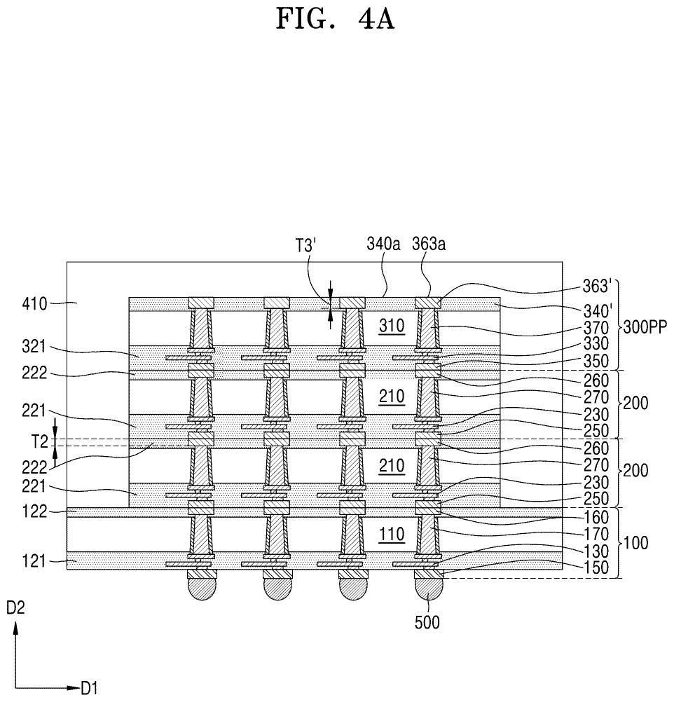

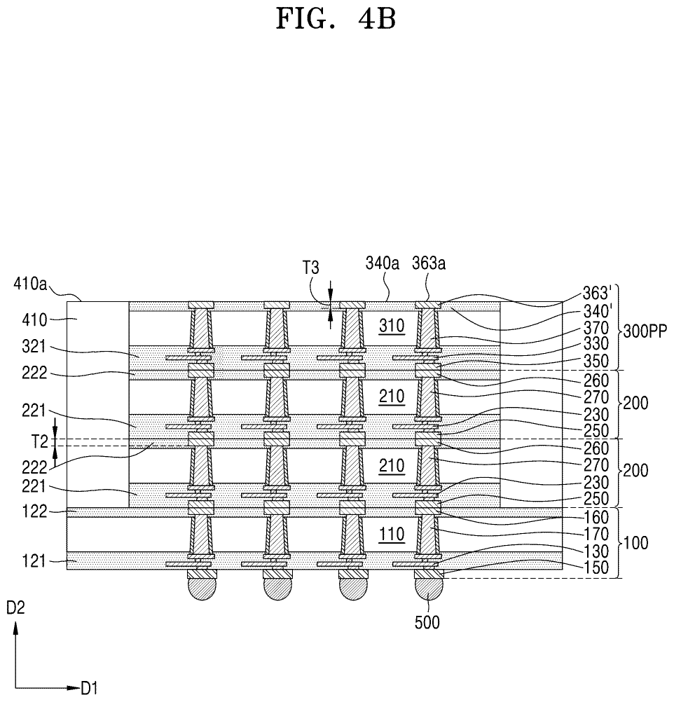

FIGS. 4A and 4B are diagrams of a process of manufacturing a semiconductor package, according to some embodiments. Hereinafter, descriptions which are the same as or similar to the above descriptions are omitted.

Referring to FIG. 4A, a first semiconductor chip 100 may be prepared at a wafer level. A second semiconductor chip 200 may be prepared at a chip level. The second semiconductor chip 200 may be provided on the first semiconductor chip 100. The second semiconductor chip 200 may be directly bonded to the first semiconductor chip 100 by a thermal compression process. The arrangement of the second semiconductor chip 200 may be repeatedly performed, and thus, a plurality of stacked second semiconductor chips 200 may be manufactured. A thermal compression process may be performed on the second semiconductor chips 200, and the second semiconductor chips 200 may be directly bonded to each other.

A third preliminary semiconductor chip 300PP may be prepared at a chip level. The third preliminary semiconductor chip 300PP may include a third semiconductor substrate 310, third integrated circuits 315, a third lower insulation layer 321, third lower pads 350, third wiring patterns 330, third through vias 370, and a third upper insulation layer 340, which are as described above with reference to FIGS. 3A and 3B. The third preliminary semiconductor chip 300PP may include the conductive pad 363 of FIGS. 3A and 3B and may not include a protection pad 365. A thickness T3′ of the conductive pad 363 may be about 1.5 to 2.5 times a thickness T2 of the second upper pads 260. Although not shown, as in FIG. 3B, the conductive pad 363 may include a first conductive pad 361 and a second conductive pad 362.

A first molding layer 410 may be formed on an upper surface of the first semiconductor chip 100 and may be on and at least partially cover sidewalls of the second semiconductor chips 200, a sidewall of the third preliminary semiconductor chip 300PP, and an upper surface of the preliminary third semiconductor chip 300PP. In this case, the upper surface of the preliminary third semiconductor chip 300PP may include an upper surface 340a of the third upper insulation layer 340′ and an upper surface 363a of the conductive pad 363. That is, the first molding layer 410 may be on and at least partially cover the upper surface 340a of the third upper insulation layer 340′ and the upper surface 363a of the conductive pad 363.

Referring to FIG. 4B, a grinding process may be performed on the first molding layer 410, and thus, the upper surface 340a of the third upper insulation layer 340′ and the upper surface 363a of the conductive pad 363 may be exposed. The grinding process may include a CMP process. A portion of the first molding layer 410 may be removed in the middle of the grinding process. After the grinding process ends, the upper surface 340a of the third upper insulation layer 340′ may be coplanar with the upper surface 363a of the conductive pad 363 and the upper surface 410a of the first molding layer 410. When performing the grinding process, a portion of the third upper insulation layer 340′ and a portion of the conductive pad 363 may be further removed. Accordingly, the conductive pad 363 may be thinned. After the grinding process ends, the thickness T3′ of the conductive pad 363 may be about 20% to about 100% of the thickness T2 of the second upper pads 260.

Referring again to FIGS. 3A and 3B, a protection pad 365 may be formed on the exposed upper surface 363a of the conductive pad 363. An operation of forming the protection pad 365 may be performed by an electro-less plating process. Accordingly, manufacturing of the third upper pads 360′ and the third semiconductor chip 300 may be completed. Each of the third upper pads 360′ may include the conductive pad 363 and the protection pad 365. According to the embodiments described above, manufacturing of the chip stack unit 10B may be completed.

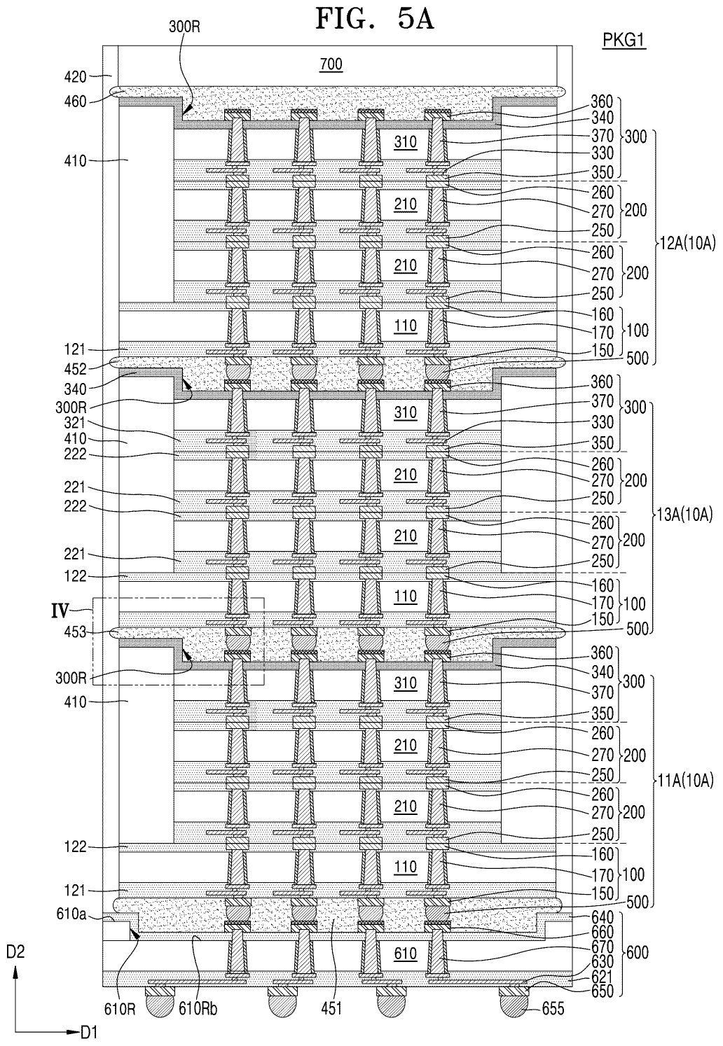

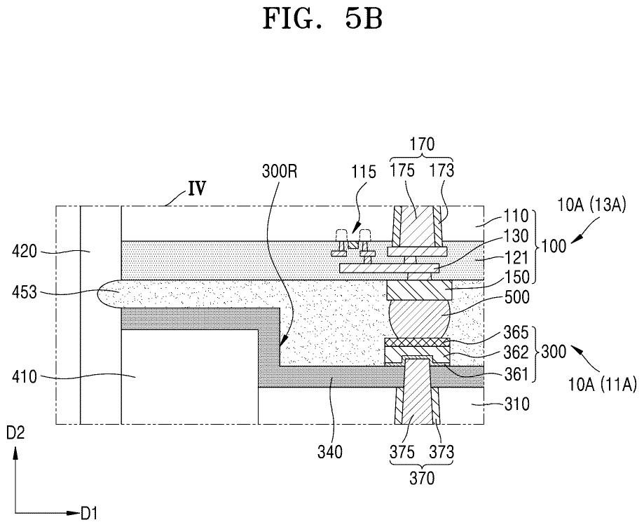

FIG. 5A is a cross-sectional view illustrating a semiconductor package PKG1 according to some embodiments. FIG. 5B is an enlarged view of a region IV of the semiconductor package of FIG. 5A.

Referring to FIGS. 5A and 5B, the semiconductor package PKG1 may include a lower chip 600, solder ball terminals 655, a plurality of chip stack units 11A, 12A, and 13A, an upper dummy chip 700, a second molding layer 420, a first insulation film 451, a second insulation film 452, a third insulation film 453, and a gap-fill film 460.

The chip stack units 11A, 12A, and 13A may include a first chip stack unit 11A, a second chip stack unit 12A, and a third chip stack unit 13A. Each of the first chip stack unit 11A, the second chip stack unit 12A, and the third chip stack unit 13A may be substantially the same as the chip stack unit 10A described above with reference to FIG. 1A. For example, each of the first chip stack unit 11A, the second chip stack unit 12A, and the third chip stack unit 13A may include the first semiconductor chip 100, the second semiconductor chips 200, the third semiconductor chip 300, the solder balls 500, and the first molding layer 410 each described above with reference to FIG. 1A to 1D or 2A to 2C. Two adjacent semiconductor chips of the first semiconductor chip 100, the second semiconductor chips 200, and the third semiconductor chip 300 may be directly bonded to each other.

The first chip stack unit 11A may be a lowermost chip stack unit. The second chip stack unit 12A may be an uppermost chip stack unit. The third chip stack unit 13A may be disposed between the first chip stack unit 11A and the second chip stack unit 12A. The number of stacked chip stack units 11A, 12A, and 13A may be variously modified in accordance with different embodiments. For example, the semiconductor package PKG1 may include two or more third chip stack units 13A. In other embodiments, the semiconductor package PKG1 may not include the third chip stack unit 13A and may include the first chip stack unit 11A and the second chip stack unit 12A. Therefore, the semiconductor package PKG1 may include two chip stack units 10A, four chip stack units 10A, six chip stack units 10A, or eight chip stack units 10A, but embodiments are not limited thereto. In FIGS. 5A, 6, 7, and 8, for convenience, one second chip stack unit 12A is illustrated, but embodiments of the inventive concept are not limited thereto.

According to embodiments, the chip stack unit 10A described in the embodiment of FIG. 1A may be repeatedly mounted on a lower chip 600 to form the first chip stack unit 11A, the second chip stack unit 12A, and the third chip stack unit 13A.

The lower chip 600 may be a memory chip, a logic chip, an interposer chip, or a dummy chip. The lower chip 600 may be manufactured by using a buffer wafer. A width of the lower chip 600 in the D1 direction may be greater than widths of the first to third chip stack units 11A, 12A, and 13A.

The lower chip 600 may include a fourth semiconductor substrate 610, a fourth lower insulation layer 621, fourth lower pads 650, fourth wiring patterns 630, fourth through vias 670, fourth upper pads 660, and a fourth upper insulation layer 640. Unless separately described, the materials, arrangement, and electrical connection relationship of the fourth semiconductor substrate 610, the fourth lower insulation layer 621, the fourth lower pads 650, the fourth wiring patterns 630, the fourth through vias 670, the fourth upper pads 660, and the fourth upper insulation layer 640 may be the same as the first semiconductor substrate 110, the first lower insulation layer 121, the first lower pads 150, the first wiring patterns 130, the first through vias 170, the first upper pads 160, and the first upper insulation layer 122.

The lower chip 600 may further include fourth integrated circuits (not shown), and the fourth integrated circuits may be provided on a lower surface of the fourth semiconductor substrate 610. The fourth integrated circuits may include memory circuits, logic circuits, and a combination thereof. In other embodiments, the lower chip 600 may not include the fourth integrated circuits. In this case, the lower chip 600 may function as an interposer chip or a dummy chip.

The fourth lower insulation layer 621 may be provided on the lower surface of the fourth semiconductor substrate 610. The fourth wiring patterns 630 may be provided in the fourth lower insulation layer 621. The fourth lower pads 650 may be disposed on a lower surface of the fourth lower insulation layer 621. The fourth lower pads 650 may be electrically connected to the fourth through vias 670 through the fourth wiring patterns 630. The fourth lower pads 650 may include metal, which differs from that of the first upper pads 160. The fourth lower pads 650 may include, for example, Ni, Al, or a combination thereof.

The solder terminals 655 may be disposed on a lower surface of the lower chip 600. The solder terminals 655 may be provided on lower surfaces of the fourth lower pads 650 and may contact the fourth lower pads 650.

The fourth through vias 670 may be provided in the fourth semiconductor substrate 610. The fourth through vias 670 may further pass through at least a portion of the fourth lower insulation layer 621. The fourth through vias 670 may be electrically connected to the fourth lower pads 650 through the fourth wiring patterns 630. Each of the fourth through vias 670 may include a fourth conductive via and a fourth barrier layer. The fourth barrier layer may be disposed between the fourth conductive via and the fourth semiconductor substrate 610. The fourth barrier layer may include a metal which differs from that of the fourth conductive via.

The fourth semiconductor substrate 610 may include a recess portion 610R on an upper surface 610a thereof. The recess portion 610R of the fourth semiconductor substrate 610 may be provided in a center region of the fourth semiconductor substrate 610, with respect to a plane.

The recess portion 610R of the fourth semiconductor substrate 610 may be formed by removing the center region of the fourth semiconductor substrate 610. A bottom surface 610Rb of the recess portion 610R of the fourth semiconductor substrate 610 may be provided at a level which is lower in the D2 direction than the upper surface 610a of an edge region of the fourth semiconductor substrate 610.

The fourth upper insulation layer 640 may be provided on the fourth semiconductor substrate 610 and in the recess portion 610R. The fourth upper insulation layer 640 may be on and at least partially cover the upper surface 610a of the fourth semiconductor substrate 610, the bottom surface 610Rb of the recess portion 610R, and a sidewall of the recess portion 610R. The fourth upper insulation layer 640 may include a silicon-based insulating material. For example, the fourth upper insulation layer 640 may include a silicon oxide layer, a silicon nitride layer, and a silicon oxynitride layer, which are stacked. The fourth through vias 670 may further pass through at least a portion of the fourth upper insulation layer 640. Being electrically connected to the lower chip 600 may denote being electrically connected to the fourth through vias 670 or the fourth integrated circuits.

The fourth upper pads 660 may be provided on the fourth through vias 670 and an upper surface of the fourth upper insulation layer 640. End portions of the fourth through vias 670 may protrude to inner portions of lower portions of the fourth upper pads 660, but embodiments are not limited thereto. Each of the fourth upper pads 660 may include a lower conductive pad and a lower protection pad. The lower conductive pad may include, for example, copper. A thickness of the lower conductive pad may be greater than that of the lower protection pad. The lower protection pad may be on and at least partially cover an upper surface of the lower conductive pad. The lower protection pad may include, for example, Au. The fourth upper pads 660 may be electrically connected to the solder terminals 655 through the fourth through vias 670.

The first chip stack unit 11A may be disposed on an upper surface of the lower chip 600 and may be electrically connected to the lower chip 600. For example, solder bumps 500 of the first chip stack unit 11A may be aligned on the fourth lower pads 650 of the lower chip 600 and may be bonded to the fourth lower pads 650. Therefore, the first chip stack unit 11A may be electrically connected to the lower chip 600 through the solder bumps 500. For example, the first chip stack unit 11A may be electrically connected to the fourth wiring patterns 630 through the solder bumps 500. The solder bumps 500 may be provided in the recess portion 610R of the fourth semiconductor substrate 610. Accordingly, a height of the semiconductor package PKG1 may decrease, and the semiconductor package PKG1 may be miniaturized. The solder bumps 500 of the first chip stack unit 11A may be first solder bumps.

A first insulation film 451 may be provided between the lower chip 600 and the first chip stack unit 11A and may seal sidewalls of the solder bumps 500 of the first chip stack unit 11A. The first insulation film 451, for example, may be provided in the recess portion 610R and on a lower surface of the first semiconductor chip 100 of the first chip stack unit 11A and may be on and at least partially cover the fourth upper insulation layer 640. A portion of the first insulation film 451 may protrude more sideward in the D1 direction than an outer sidewall of the first chip stack unit 11A, but is not limited thereto. The first insulation film 451 may include a nonconductive film. The first insulation film 451 may include, for example, an insulating polymer.

The third chip stack unit 13A may be mounted on the first stack chip unit 11A. Solder bumps 500 of the third chip stack unit 13A may be aligned on the third upper pads 360 of the first chip stack unit 11A and may be bonded to the third upper pads 360. The solder bumps 500 of the third chip stack unit 13A may be third solder bumps. An operation of bonding the third chip stack unit 13A to the first chip stack unit 11A may include an operation of connecting the solder bumps 500 of the third chip stack unit 13A with the third upper pads 360 of the first chip stack unit 11A through a reflow process. As in FIG. 1D, each of the solder bumps 500 of the third chip stack unit 13A may contact a corresponding protection pad (365 of FIG. 1D) of the third upper pads 360 of the first chip stack unit 11A. Therefore, the third chip stack unit 13A may be electrically connected to the first chip stack unit 11A through the solder bumps 500. The solder bumps 500 may be provided in the recess 300R of the first chip stack unit 11A.

Accordingly, a height of the semiconductor package PKG1 may decrease, and the semiconductor package PKG1 may be miniaturized.

A third insulation film 453 may be provided between the first chip stack unit 11A and the third chip stack unit 13A and may seal sidewalls of the solder bumps 500 of the third chip stack unit 13A. For example, the third insulation film 453 may be on and at least partially cover an upper surface of the third upper insulation layer 340 of the third chip stack unit 13A and a lower surface of the first lower insulation layer 121 of the first semiconductor chip 100 of the second chip stack unit 12A. The third insulation film 453 may be provided in the recess 300R of the first chip stack unit 11A and on the first molding layer 410. Accordingly, a height of the semiconductor package PKG1 may be reduced. A portion of the third insulation film 453 may protrude more sideward in the D1 direction than an outer sidewall of the third chip stack unit 13A and the outer sidewall of the first chip stack unit 11A, but embodiments are not limited thereto. The third insulation film 453 may include a nonconductive film. The third insulation film 453 may include, for example, an insulating polymer. For example, the third insulation film 453 may include the same material as that of the first insulation film 451.

The second chip stack unit 12A may be mounted on the third stack chip unit 13A. For example, the solder bumps 500 of the second chip stack unit 12A may be disposed on the third upper pads 360 of the third chip stack unit 13A. The solder bumps 500 of the second chip stack unit 12A may be bonded to the third upper pads 360 of the third chip stack unit 13A by a reflow process. Each of the solder bumps 500 of the second chip stack unit 12A may contact a corresponding protection pad (365 of FIG. 1D) of the third upper pads 360 of the third chip stack unit 13A. Therefore, the second chip stack unit 12A may be electrically connected to the third chip stack unit 13A through the solder bumps 500. The solder bumps 500 of the second chip stack unit 12A may be second solder bumps. The second chip stack unit 12A may be electrically connected to the first chip stack unit 11A through the solder bumps 500 of the second chip stack unit 12A and the third chip stack unit 13A.

The solder bumps 500 of the second chip stack unit 12A may be provided in the recess 300R of the third chip stack unit 13A. Accordingly, a height of the semiconductor package PKG1 may decrease, and the semiconductor package PKG1 may be miniaturized.

A second insulation film 452 may be provided between the second chip stack unit 12A and the third chip stack unit 13A and may seal the sidewalls of the solder bumps 500 of the third chip stack unit 13A. The second insulation film 452 may be provided in the recess 300R of the third chip stack unit 13A and may cover the third upper insulation layer 340 of the third chip stack unit 13A and the first lower insulation layer 121 of the second chip stack unit 12A. A portion of the second insulation film 452 may protrude more sideward than the outer sidewall of the third chip stack unit 13A and an outer sidewall of the second chip stack unit 12A, but is not limited thereto. The second insulation film 452 may include a nonconductive film. The second insulation film 452 may include, for example, an insulating polymer. For example, the second insulation film 452 may include the same material as that of each of the third insulation film 453 and the first insulation film 451.

The upper dummy chip 700 may be disposed on the second chip stack unit 12A. The upper dummy chip 700 may not be electrically connected to the second chip stack unit 12A. The upper dummy chip 700 may include, for example, a semiconductor substrate such as a silicon substrate. The upper dummy chip 700 may not include integrated circuits. The upper dummy chip 700 may not include chip pads and solder balls on a lower surface thereof. The upper dummy chip 700 may protect the third chip stack unit 13A. A thermal conductance of the upper dummy chip 700 may be greater than that of the first molding layer 410 and that of the second molding layer 420. Therefore, when the semiconductor package PKG1 operates, heat occurring in the first to third chip stack units 11A, 12A, and 13A may be smoothly transferred to the upper dummy chip 700. The semiconductor package PKG1 may have an enhanced heat dissipation characteristic. A height of the semiconductor package PKG1 may be controlled by adjusting a height of the upper dummy chip 700.

The upper dummy chip 700 may be disposed apart from the second chip stack unit 12A. For example, the upper dummy chip 700 may be disposed apart from the third upper insulation layer 340 and the third upper pads 360 of the second chip stack unit 12A. A gap-fill film 460 may be provided in a gap region between the second chip stack unit 12A and the upper dummy chip 700. The gap-fill film 460 may be provided in the recess 300R of the second chip stack unit 12A and may at least partially fill the gap region. For example, the gap-fill film 460 may be on and at least partially cover the third upper insulation layer 340 and the third upper pads 360 of the second chip stack unit 12A and may be on and at least partially cover the lower surface of the upper dummy chip 700. The gap-fill film 460 may be on and cover at least a portion of an upper surface of the third upper insulation layer 340 on the first molding layer 410 of the first chip stack unit 11A. An outer sidewall of the gap-fill film 460 may protrude more sideward in the D1 direction than the outer sidewall of the second chip stack unit 12A and an outer sidewall of the upper dummy chip 700, but is not limited thereto.

For example, a thermal conductance of the gap-fill film 460 may be greater than that of the first molding layer 410 and that of the second molding layer 420. When the semiconductor package PKG1 operates, heat occurring in the first to third chip stack units 11A, 12A, and 13A may be more smoothly transferred to the upper dummy chip 700 through the gap-fill film 460. The semiconductor package PKG1 may have an enhanced heat dissipation characteristic.

For example, the gap-fill film 460 may include a material which differs from that of each of the first insulation film 451, the second insulation film 452, and the third insulation film 453. The gap-fill film 460 may include a thermal interface material (TIM) or a solder paste material. The gap-fill film 460 may have a relatively high thermal conductance.

As another example, the gap-fill film 460 may include the same material as that of each of the first insulation film 451, the second insulation film 452, and the third insulation film 453. For example, the second insulation film 452 may include a nonconductive film.

The second molding layer 420 may be disposed on the lower chip 600. The second molding layer 420 may be provided on the upper surface 610a of the fourth semiconductor substrate 610 and may be on and at least partially cover the sidewalls of the first to third chip stack units 11A, 12A, and 13A and sidewalls of the upper dummy chip 700. The second molding layer 420 may include an insulating polymer such as an epoxy molding compound (EMC). The second molding layer 420 may be on and at least partially cover sidewalls of the first insulation film 451, sidewalls of the second insulation film 452, sidewalls of the third insulation film 453, and sidewalls of the gap-fill film 460. The first molding layer 410 may be an inner molding layer, and the second molding layer 420 may be an outer molding layer.

In a case where semiconductor chips are repeatedly and directly bonded to the lower chip 600 by a thermal compression process, a defect of the semiconductor chips may occur in performing the thermal compression process. The defect may include the occurrence of warpage of the semiconductor chips or unstable bonding between the semiconductor chips. When the number of directly bonded semiconductor chips is more than a certain range, defects of the semiconductor chips may increase. When a defect occurs in at least one of the semiconductor chips, this may cause a defect of the semiconductor package PKG1.

According to embodiments, the chip stack unit 10A including directly bonded first to third semiconductor chips 100, 200, and 300 may be prepared. Before the chip stack unit 10A is mounted, a test process of the chip stack unit 10A may be performed. The chip stack unit 10A, which has undergone the test process may be mounted on the lower chip 600. According to embodiments, each of the first chip stack unit 11A, the second chip stack unit 12A, and the third chip stack unit 13A may be the chip stack unit 10A, which has undergone a test. Therefore, even when a defect occurs in a direct bonding process of the first to third semiconductor chips 100, 200, and 300, the chip stack unit 10A where the defect occurs may not be used in manufacturing of the semiconductor package PKG1. Accordingly, a yield rate of the semiconductor package PKG1 may be enhanced.

According to embodiments, the first chip stack unit 11A, the second chip stack unit 12A, and the third chip stack unit 13A may be mounted by using the solder bumps 500. Therefore, the total number of first to third semiconductor chips 100, 200, and 300 included in each of the first to third chip stack units 11A, 12A, and 13A may satisfy a condition within a certain range, and moreover, the total number of first to third semiconductor chips 100, 200, and 300 included in the semiconductor package PKG1 may increase. Accordingly, the semiconductor package PKG1 may have high performance and high capacity, and bonding between the first to third semiconductor chips 100, 200, and 300 may be good. The semiconductor package PKG1 may be enhanced in reliability and may be manufactured at a high yield rate.

According to embodiments, as in FIG. 1A, because a level difference A1 between the upper surface 410a of the first molding layer 410 and the upper surface 310a of the third semiconductor substrate 310 in the chip stack unit 10A satisfies a condition of about 50% to about 100% of a sum A2 of a height of the first solder bumps 500 and a thickness of the first lower pads 150 in FIG. 1A, the semiconductor package PKG1 may be more effectively miniaturized.

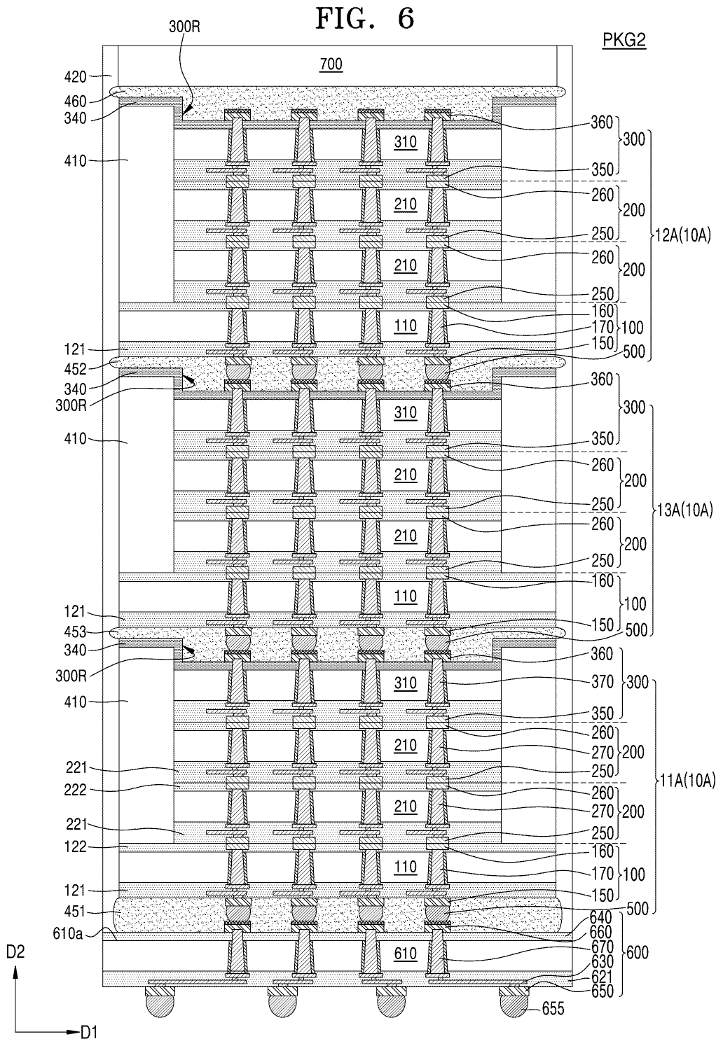

FIG. 6 is a cross-sectional view illustrating a semiconductor package PKG2 according to some embodiments.

Referring to FIG. 6, the semiconductor package PKG2 may include a lower chip 600, solder ball terminals 655, a first chip stack unit 11A, a second chip stack unit 12A, a third chip stack unit 13A, an upper dummy chip 700, a second molding layer 420, a first insulation film 451, a second insulation film 452, a third insulation film 453, and a gap-fill film 460.

The lower chip 600 may include a fourth semiconductor substrate 610, a fourth lower insulation layer 621, fourth lower pads 650, fourth wiring patterns 630, fourth through vias 670, fourth upper pads 660, and a fourth upper insulation layer 640, which are as described above with reference to FIG. 5A. The fourth semiconductor substrate 610 may not include a recess portion (610R of FIG. 5A). An upper surface 610a of the fourth semiconductor substrate 610 may be substantially flat. For example, an upper surface 610a of an edge region of the fourth semiconductor substrate 610 may be at a level in the D2 direction, which is substantially the same as an upper surface 610a of a center region of the fourth semiconductor substrate 610. The fourth upper insulation layer 640 may be on and at least partially cover the upper surface 610a of the fourth semiconductor substrate 610.

Solder bumps 500 of the first chip stack unit 11A may contact the fourth upper pads 660. A first insulation film 451 may be provided in a gap region between the lower chip 600 and the second chip stack unit 12A and may be on and at least partially cover an upper surface of the fourth upper insulation layer 640 and sidewalls of the solder bumps 500 of the first chip stack unit 11A.

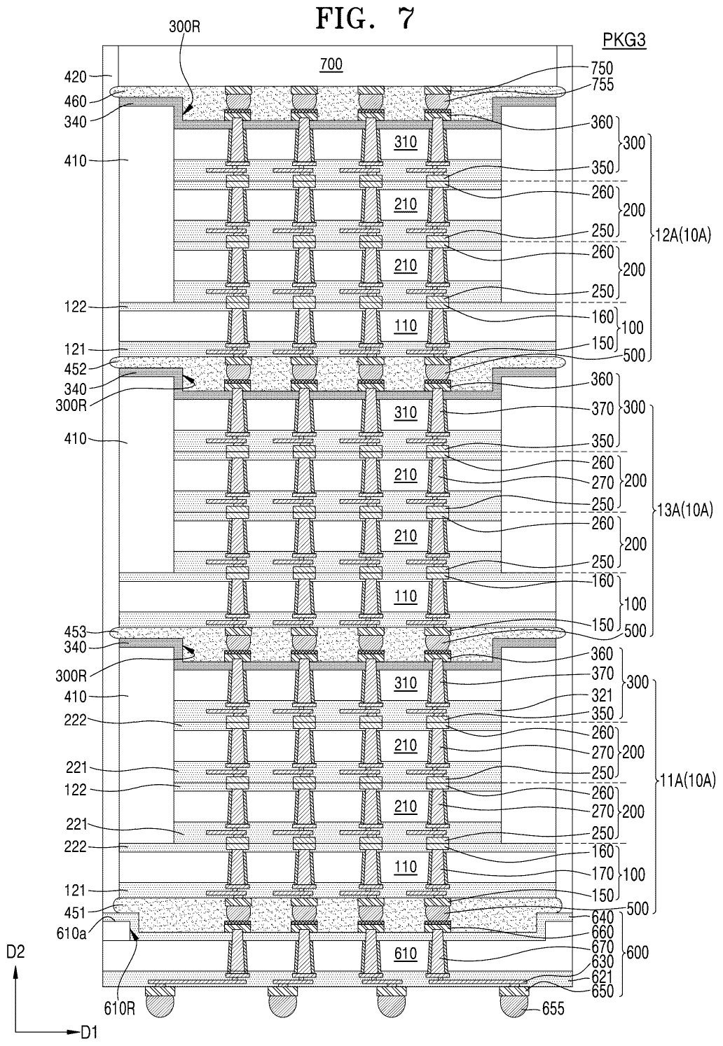

FIG. 7 is a cross-sectional view illustrating a semiconductor package PKG3 according to some embodiments.

Referring to FIG. 7, the semiconductor package PKG3 may include a lower chip 600, solder ball terminals 655, a first chip stack unit 11A, a second chip stack unit 12A, a third chip stack unit 13A, an upper dummy chip 700, a second molding layer 420, a first insulation film 451, a second insulation film 452, a third insulation film 453, and a gap-fill film 460.

The upper dummy chip 700 may include dummy pads 750 and may not include integrated circuits. The dummy pads 750 may be provided on a lower surface of the upper dummy chip 700. The dummy pads 750 may include a metal material.

The dummy solder bumps 755 may be disposed between the second chip stack unit 12A and the upper dummy chip 700. For example, the dummy solder bumps 755 may be disposed between the dummy pads 750 and third upper pads 360 of the second chip stack unit 12A. The dummy solder bumps 755 may physically support the upper dummy chip 700. A thermal conductance of the dummy solder bumps 755 may be greater than that of the first molding layer 410 and that of the second molding layer 420. The dummy solder bumps 755 may function as thermal bumps. For example, when the semiconductor package PKG3 operates, heat occurring in the first to third chip stack units 11A, 12A, and 13A may be smoothly transferred to the upper dummy chip 700 through the dummy solder bumps 755. The semiconductor package PKG3 may have an enhanced heat dissipation characteristic.

The gap-fill film 460 may be provided in a gap region between the second chip stack unit 12A and the upper dummy chip 700 and may seal sidewalls of the dummy solder bumps 755.

Unlike the illustration, the fourth semiconductor substrate 610 may not include a recess portion 610R.

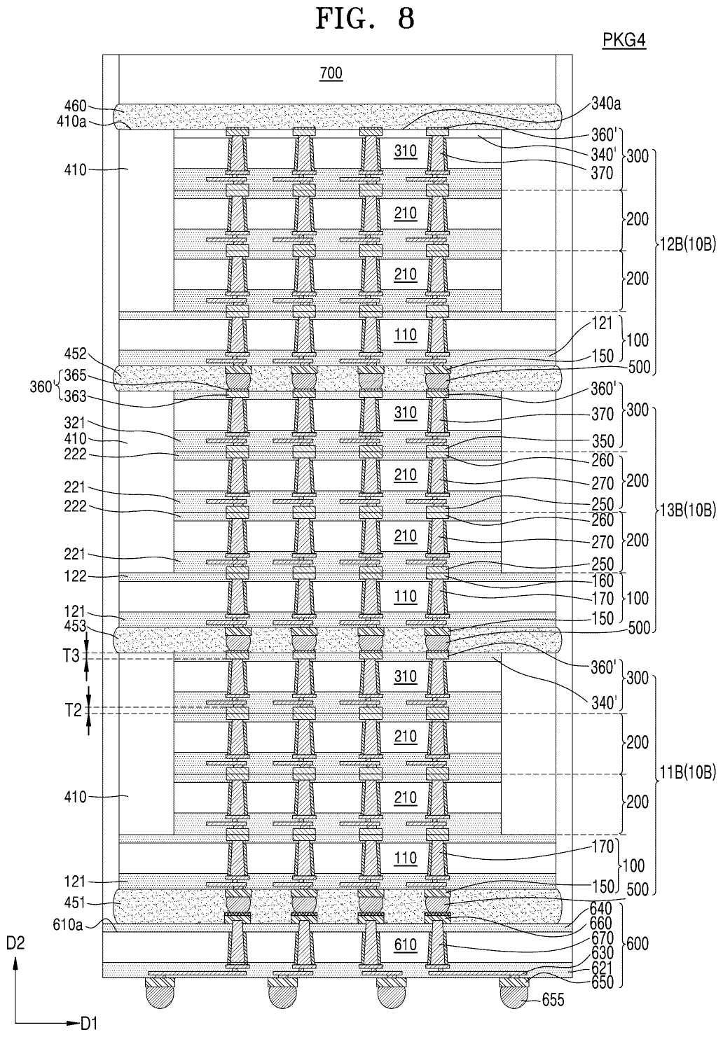

FIG. 8 is a cross-sectional view illustrating a semiconductor package PKG4 according to some embodiments.

Referring to FIG. 8, the semiconductor package PKG4 may include a lower chip 600, solder ball terminals 655, a first chip stack unit 11A, a second chip stack unit 12A, a third chip stack unit 13A, an upper dummy chip 700, a second molding layer 420, a first insulation film 451, a second insulation film 452, a third insulation film 453, and a gap-fill film 460.

Each of the first chip stack unit 11A, the second chip stack unit 12A, and the third chip stack unit 13A may be substantially the same as the chip stack unit 10B described above with reference to FIGS. 3A and 3B. For example, an upper surface 340a of a third upper insulation layer 340′ may be provided at a level which is substantially the same as an upper surface 410a of a first molding layer 410 and an upper surface 363a of a conductive pad 363. The conductive pad 363 may be provided in the third upper insulation layer 340′. A protection pads 365 may be provided on the conductive pad 363.

Solder bumps 500 of the third chip stack unit 13A may contact third upper pads 360′ of the first chip stack unit 11A. The third chip stack unit 13A may be electrically connected to the first chip stack unit 11A through the solder bumps 500. Like, solder bumps 500 of the second chip stack unit 12A may be disposed on third upper pads 360 of the third chip stack unit 13A. The second chip stack unit 12A may be electrically connected to the third chip stack unit 13A through the solder bumps 500.

The fourth semiconductor substrate 610 may include an upper surface 610a, which is substantially flat, as described above with reference to FIG. 6. The fourth semiconductor substrate 610 may not include a recess portion (610R of FIG. 5A). On the other hand, as in FIG. 5A, the fourth semiconductor substrate 610 may include a recess portion 610R on an upper surface thereof as in FIG. 5A. As another example, as in FIG. 7, the upper dummy chip 700 may include dummy pads 750, and the dummy solder bumps 755 may be disposed between the second chip stack unit 12A and the dummy pads 750.

At least two of the embodiments may be combined with each other.

The embodiments are not for limiting but are for describing the inventive concept, and the scope of the inventive concept is not limited by the embodiments. The scope of the inventive concept is to be construed by the appended claims, and all variations within an equivalent range are to be construed as being included in the scope of the inventive concept.

While the inventive concept has been particularly shown and described with reference to embodiments thereof, it will be understood that various changes in form and details may be made therein without departing from the spirit and scope of the following claims.

What is claimed is:

1. A semiconductor package comprising:
a first semiconductor chip;
a second semiconductor chip on the first semiconductor chip and directly bonded to the first semiconductor chip;
a third semiconductor chip on the second semiconductor chip and directly bonded to the second semiconductor chip; and
a molding layer on an upper surface of the first semiconductor chip and on a sidewall of the second semiconductor chip and a sidewall of the third semiconductor chip,
wherein the third semiconductor chip comprises:
a third semiconductor substrate including an upper surface at a level, which is lower than an upper surface of the molding layer; and
a third upper insulation layer on the upper surface of the third semiconductor substrate, the upper surface of the molding layer, and an inner sidewall of the molding layer.

2. The semiconductor package of claim 1, wherein the third semiconductor chip further comprises:
a third through via in the third semiconductor substrate; and
a third upper pad provided on an upper surface of the third upper insulation layer to electrically contact the third through via, and
an upper surface of the third upper pad is at a level, which is lower than the upper surface of the molding layer.

3. The semiconductor package of claim 2, wherein a portion of the third upper insulation layer is on the upper surface of the molding layer, and
wherein the upper surface of the third upper pad is at a level, which is lower than an upper surface of the portion of the third upper insulation layer.

4. The semiconductor package of claim 2, wherein the first semiconductor chip comprises a first semiconductor substrate and a first upper pad on the first semiconductor substrate,
the second semiconductor chip comprises:
a second lower pad on a lower surface of a second semiconductor substrate;
a second upper pad on an upper surface of the second semiconductor substrate; and
a second through via provided in the second semiconductor substrate and electrically connected to the second lower pad and the second upper pad,
the third semiconductor chip further comprises:
a third lower pad on a lower surface of the third semiconductor substrate; and
a third through via provided in the third semiconductor substrate and electrically connected to the third lower pad and the third upper pad,
the third lower pad is directly bonded to the second upper pad, and
the second lower pad is directly bonded to the first upper pad.

5. The semiconductor package of claim 4, wherein the third upper pad comprises a metal which differs from a metal of each of the first upper pad, the second lower pad, the second upper pad, and the third lower pad, and
wherein the third lower pad comprises a same metal as metal of each of the first upper pad, the second lower pad, and the second upper pad.

6. The semiconductor package of claim 4, wherein the first semiconductor chip further comprises:
a first lower pad on a lower surface of the first semiconductor substrate; and
a solder bump on a lower surface of the first lower pad,
the first lower pad comprises a metal which differs from a metal of each of the first upper pad, the second lower pad, the second upper pad, and the third lower pad, and
the first upper pad comprises a same metal as metal of each of the second lower pad, the second upper pad, and the third lower pad.

7. The semiconductor package of claim 4, wherein the first semiconductor chip further comprises a first upper insulation layer on an upper surface of the first semiconductor substrate,
the second semiconductor chip further comprises:
a second lower insulation layer on the lower surface of the second semiconductor substrate; and
a second upper insulation layer on the upper surface of the second semiconductor substrate,
the third semiconductor chip further comprises a third lower insulation layer on the lower surface of the third semiconductor substrate,
the second lower insulation layer is directly bonded to the first upper insulation layer, and
the third lower insulation layer is directly bonded to the second upper insulation layer.

8. The semiconductor package of claim 2, wherein the third upper pad comprises:
a seed pad on an end portion of the third through via and the third upper insulation layer;
a conductive pad on the seed pad; and
a protection pad on an upper surface of the conductive pad,
the conductive pad comprises a metal which differs from a metal of each of the protection pad and the seed pad, and
a thickness of the conductive pad is greater than a thickness of the seed pad and a thickness of the protection pad in a stacking direction of the first, second, and third semiconductor chips.

9. The semiconductor package of claim 1, wherein a width of the first semiconductor chip is greater than a width of the second semiconductor chip and a width of the third semiconductor chip in a direction parallel to the upper surface of the first semiconductor chip, and
an outer sidewall of the molding layer is aligned with a sidewall of the first semiconductor chip in a stacking direction of the first, second, and third semiconductor chips.

10. The semiconductor package of claim 1, wherein the first semiconductor chip further comprises:
a first semiconductor substrate;
a first lower pad on a lower surface of the first semiconductor substrate; and
a solder bump on a lower surface of the first lower pad,
a level difference between the upper surface of the molding layer and the upper surface of the third semiconductor substrate is 50% to 100% of a sum of a thickness of the first lower pad and a thickness of the solder bump in a stacking direction of the first, second, and third semiconductor chips.

11. A semiconductor package comprising:
a semiconductor substrate including wiring patterns;
a first chip stack unit on the semiconductor substrate and electrically connected to the wiring patterns through first solder bumps;
a second chip stack unit on the first chip stack unit and electrically connected to the first chip stack unit through second solder bumps;
a first insulation film between the semiconductor substrate and the first chip stack unit and on sidewalls of the first solder bumps; and
a second insulation film on sidewalls of the second solder bumps,
wherein each of the first chip stack unit and the second chip stack unit comprises:
a first semiconductor chip;
a second semiconductor chip on the first semiconductor chip and directly bonded to the first semiconductor chip; and
a first molding layer on an upper surface of the first semiconductor chip and on a sidewall of the second semiconductor chip.

12. The semiconductor package of claim 11, further comprising:
an upper dummy chip on the second chip stack unit and the first molding layer; and
a gap-fill film between the second chip stack unit and the upper dummy chip, wherein the upper dummy chip is not electrically connected to the second chip stack unit.

13. The semiconductor package of claim 12, further comprising a second molding layer on an upper surface of the semiconductor substrate and on an outer sidewall of the first chip stack unit, an outer sidewall of the second chip stack unit, and an outer sidewall of the upper dummy chip,
wherein a thermal conductance of the upper dummy chip is greater than a thermal conductance of the first molding layer and a thermal conductance of the second molding layer.

14. The semiconductor package of claim 13, wherein the second molding layer is further on sidewalls of the first insulation film and sidewalls of the second insulation film.

15. The semiconductor package of claim 11, wherein each of the first chip stack unit and the second chip stack unit comprises:
a third semiconductor chip on the second semiconductor chip and directly bonded to the second semiconductor chip, and
wherein the first molding layer is further on a sidewall of the third semiconductor chip.

16. The semiconductor package of claim 15, wherein the third semiconductor chip further comprises:
a third semiconductor substrate;
a third upper insulation layer an upper surface of the third semiconductor substrate; and
a third upper pad on an upper surface of the third upper insulation layer, an upper surface of the third upper pad is at a level, which is lower than an upper surface of the first molding layer, and
the third upper insulation layer extends to an inner sidewall of the first molding layer and the upper surface of the first molding layer.

17. The semiconductor package of claim 11, further comprising:
a third chip stack unit between the first chip stack unit and the second chip stack unit and electrically connected to the first chip stack unit and the second chip stack unit through third solder bumps; and
a third insulation film on sidewalls of the third solder bumps,
wherein the second solder bumps are between the third chip stack unit and the second chip stack unit, and
wherein the second solder bumps are electrically connected to the first chip stack unit through the third chip stack unit.

18. A semiconductor package comprising:
a semiconductor substrate including wiring patterns;
a plurality of solder ball terminals on a lower surface of the semiconductor substrate;
a first chip stack unit on an upper surface of the semiconductor substrate and electrically connected to the wiring patterns through first solder bumps;
a second chip stack unit on the first chip stack unit, the second chip stack unit including second solder bumps on a lower surface thereof;
an upper dummy chip on the second chip stack unit;
a gap-fill film provided between the second chip stack unit and the upper dummy chip;
a first insulation film between the semiconductor substrate and the first chip stack unit and on sidewalls of the first solder bumps;
a second insulation film on sidewalls of the second solder bumps; and
an outer molding layer on the upper surface of the semiconductor substrate and on a sidewall of the first chip stack unit, a sidewall of the second chip stack unit, a sidewall of the first insulation film, a sidewall of the second insulation film, a sidewall of the gap-fill film, and a sidewall of the upper dummy chip,
wherein each of the first chip stack unit and the second chip stack unit comprises:
a first semiconductor chip including a first semiconductor substrate, a first lower insulation layer, a first lower pad, a first conductive via, a first upper insulation layer, and a first upper pad;
a second semiconductor chip on the first semiconductor chip, and including a second semiconductor substrate, a second lower insulation layer, a second lower pad, a second conductive via, a second upper insulation layer, and a second upper pad;
a third semiconductor chip on the second semiconductor chip, and including a third semiconductor substrate, a third lower insulation layer, a third lower pad, a third conductive via, a third upper insulation layer, and a third upper pad; and
an inner molding layer on an upper surface of the first semiconductor chip and on a sidewall of the second semiconductor chip and a sidewall of the third semiconductor chip,
the third lower pad is directly bonded to the second upper pad, and
the second lower pad is directly bonded to the first upper pad.

19. The semiconductor package of claim 18, wherein the third upper pad comprises:
a conductive pad in the third upper insulation layer; and
a protection pad on an upper surface of the conductive pad and including an upper surface at a level, which is higher than an upper surface of the third upper insulation layer, and
a thickness of the conductive pad is 20% to 100% of a thickness of the second upper pad.

20. The semiconductor package of claim 18, wherein an upper surface of the third semiconductor substrate is at a level, which is lower than an upper surface of the inner molding layer,
the third upper insulation layer comprises:
a first portion on the upper surface of the third semiconductor substrate;
a second portion on an inner sidewall of the inner molding layer; and
a third portion on an upper surface of the inner molding layer, and
wherein the third upper pad is provided on the first portion of the third upper insulation layer and is electrically connected to the third conductive via.
